(19) United States
(12) Patent Application Publication
(10) Pub. No.: US 2016/0368177 A1
(43) Pub. Date: Dec. 22, 2016

(54) MOLD RELEASE FILM, PROCESS FOR ITS PRODUCTION AND PROCESS FOR PRODUCING SEMICONDUCTOR PACKAGE

(71) Applicant: Asahi Glass Company, Limited, Chiyoda-ku (JP)

(72) Inventors: Wataru KASAI, Chiyoda-ku (JP); Masami Suzuki, Chiyoda-ku (JP)

(73) Assignee: Asahi Glass Company, Limited, Chiyoda-ku (JP)

(21) Appl. No.: 15/256,980

(22) Filed: Sep. 6, 2016

Related U.S. Application Data
(63) Continuation of application No. PCT/JP2015/056732, filed on Mar. 6, 2015.

(30) Foreign Application Priority Data
Mar. 7, 2014 (JP) 2014-045460

(51) Int. Cl. B29C 33/68; B29C 45/02; B29C 43/18; H01L 23/29; B32B 27/08; B32B 37/12; H01L 21/56; B29C 45/14; B32B 27/32

(52) U.S. Cl. CPC B29C 33/68; B29C 45/14655; B29C 45/02; B29C 43/18; B32B 27/322; B32B 27/08; B32B 37/12; H01L 21/566; H01L 23/293; B29C 2045/14663; B29K 2627/18

(57) ABSTRACT

To provide a mold release film which is not easily electrically charged or curled, does not contaminate a mold, and has excellent mold followability, a process for its production, and a process for producing a semiconductor package by using the mold release film. A mold release film to be disposed on a surface of a mold which is to be in contact with a curable resin, in a process for producing a semiconductor package by disposing a semiconductor element in the mold, and sealing it with the curable resin to form a resin sealed portion, comprising a first thermoplastic resin layer to be in contact with the curable resin at the time of forming the resin sealed portion, a second thermoplastic resin layer to be in contact with the mold at the time of forming the resin sealed portion, and an interlayer disposed between the first thermoplastic resin layer and the second thermoplastic resin layer, wherein the first thermoplastic resin layer and the second thermoplastic resin layer have a storage elastic modulus at 180° C. of from 10 to 300 MPa, respectively, the difference in storage elastic modulus at 25° C. between them is at most 1,200 MPa, and their thicknesses are from 12 to 50 μm, and the interlayer includes a layer containing a polymeric antistatic agent.

### TECHNICAL FIELD

The present invention relates to a mold release film to be disposed on a cavity surface of a mold in a process for producing a semiconductor package by disposing a semiconductor element in the mold and sealing it with a curable resin to form a resin sealed portion, a process for its production, and a process for producing a semiconductor package by using the mold release film.

### BACKGROUND ART

A semiconductor chip is usually sealed with a resin for shielding and protection from outside air and mounted on a substrate, as a molded product called a package. For sealing a semiconductor chip, a curable resin such as a thermosetting resin such as an epoxy resin, is used. As the sealing method for a semiconductor chip, for example, a so-called transfer molding method or compression molding method is known wherein a substrate having a semiconductor chip mounted thereon is disposed so that the semiconductor chip is positioned at a predetermined location in the cavity of a mold, and a curable resin is filled into the cavity and cured.

Heretofore, a package is molded as a package molded article for each chip which is connected via a runner which is a flow path of a curable resin. In such a case, improvement in the releasability of the package from the mold is done, in many cases, by adjustment of the mold structure, addition of a release agent to the curable resin, etc. On the other hand, from the demand for downsizing or multi-pin modification of packages, BGA type or QFN type packages, and further, wafer level CSP (WL-CSP) type packages are increasing. In the QFN type, in order to secure the stand-off and to prevent formation of a resin burr at the terminal area, and in the BGA type and WL-CSP type, in order to improve the releasability of the package from the mold, a mold release film is often disposed on the cavity surface of the mold.

Disposition of the mold release film on the mold cavity surface is usually carried out by unwinding a long mold release film wound in a superposed state from an unwinding roll, supplying it on the mold in a state pulled by the unwinding roll and the wind-up roll, and letting it suctioned to the cavity surface by vacuum. Further, recently, it has been also practiced to provide a mold release film preliminarily cut in a short size to fit the mold (Patent Document 1).

As the mold release film, a resin film is usually used. However, such a mold release film has a problem that it is easily electrically charged. For example, in a case where a mold release film is to be used by unwinding it, static electricity is likely to be generated at the time of peeling the mold release film, and foreign matters such as dusts, etc. present in the production atmosphere are likely to be deposited on the charged mold release film to cause shape abnormalities (formation of burrs, deposition of foreign matters, etc.) of packages and mold contamination. Especially, the number of devices employing granular resins as sealing means for semiconductor chips are increasing (for example, Patent Document 2), and therefore, the shape abnormalities and mold contamination to be caused by deposition of dusts generated from the granular resins are no longer ignored.

Further, in recent years, from the demand for thinning of a package or improvement in heat dissipation properties, a package wherein a semiconductor chip is flip-chip bonded to expose the back of the chip, is increasing. This process step is called a molded underfill (Molded Underfill: MUF) step. In the MUF step, sealing is carried out in a state where the mold release film and the semiconductor chip are in direct contact (e.g. Patent Document 3) for protection and masking the semiconductor chip. At that time, if the mold release film is easily charged, there is a fear that the semiconductor chip will be broken by charging and discharging during the peeling.

As a countermeasure, (1) a method for removing an electrostatic charge by blowing ionized air to a mold release film between electrodes to which a high voltage is applied, before the mold release film is conveyed into the mold (Patent Document 4), (2) a method for reducing the surface resistance of a mold release film by incorporating carbon black (Patent Document 5), or (3) a method of applying an antistatic agent to a base material constituting a mold release film and further applying and crosslinking a crosslinkable acrylic adhesive, to provide a release layer in the mold release film (Patent Documents 6 and 7), has, for example, been proposed.

### PRIOR ART DOCUMENTS

### Patent Documents

Patent Document 1: JP-A-2009-272398
Patent Document 2: JP-A-2008-279599
Patent Document 3: JP-A-2013-123063
Patent Document 4: JP-A-2000-252309
Patent Document 5: JP-A-2002-280403
Patent Document 6: JP-A-2005-166904
Patent Document 7: JP-A-2013-084873

### DISCLOSURE OF INVENTION

### Technical Problem

However, in the method (1), although the electric charge of the mold release film may be removed, a risk of winding up of dusts by the air tends to increase, and it is not possible to prevent charging and discharging at the time of the peeling.

In the method (2), if carbon black is incorporated in an amount to sufficiently lower the surface resistance, carbon black is likely to be desorbed, whereby there will be a problem such that desorbed carbon black will stain the mold.

In the method (3), a cross-linkable acrylic adhesive is applied on one side of the base material, whereby unless the base material has certain degrees of thickness and elastic modulus, the mold release film is likely to undergo curling. If the mold release film is curled, at the time of adsorbing the mold release film to the mold, there may be a case where the mold release film is not well adsorbed to the mold. Especially, as described in Patent Document 1, when using a device for supplying a mold release film of the short length to the mold, the curling problem becomes remarkable. A release film containing a thick base material having a high elastic modulus, may not be curled, but such a release film is insufficient in mold followability, and cannot be used in applications where the mold followability is required.

An object of the present invention is to provide a mold release film which is not easily electrically charged or curled, does not contaminate a mold, and has excellent mold followability, a process for its production, and a process for producing a semiconductor package by using the mold release film.

### Solution to Problem

The present invention provides a mold release film, a process for its production and a process for producing a semiconductor package, having the following constructions [1] to [9].

[1] A mold release film to be disposed on a surface of a mold which is to be in contact with a curable resin, in a process for producing a semiconductor package by disposing a semiconductor element in the mold, and sealing it with the curable resin to form a resin sealed portion, characterized by comprising

a first thermoplastic resin layer to be in contact with the curable resin at the time of forming the resin sealed portion, a second thermoplastic resin layer to be in contact with the mold at the time of forming the resin sealed portion, and an interlayer disposed between the first thermoplastic resin layer and the second thermoplastic resin layer, wherein

the first thermoplastic resin layer and the second thermoplastic resin layer have a storage elastic modulus at 180° C. of from 10 to 300 MPa, respectively, the difference in storage elastic modulus at 25° C. between them is at most 1,200 MPa, and their thicknesses are from 12 to 50 μm, and

the interlayer includes a layer containing a polymeric antistatic agent.

[2] The mold release film according to [1], wherein the interlayer is one having the layer containing a polymeric antistatic agent, and an adhesive layer formed from an adhesive containing no polymeric antistatic agent or an adhesive layer containing a polymeric antistatic agent.
[3] The mold release film according to [1] or [2], wherein both the first thermoplastic resin layer and the second thermoplastic resin layer do not contain an inorganic additive.
[4] The mold release film according to any one of [1] to [3], wherein the peel strength between the first thermoplastic resin layer and the second thermoplastic resin as measured at 180° C. in accordance with JIS K6854-2, is at least 0.3 N/cm.
[5] The mold release film according to any one of [1] to [4], wherein the surface resistance of the layer containing a polymeric antistatic agent is at most 10¹⁰Ω/□.
[6] The mold release film according to any one of [1] to [5], wherein the curl as measured by the following measuring method is at most 1 cm:

### (Method for Measuring the Curl)

At from 20 to 25° C., a square-shaped mold release film of 10 cm×10 cm is left to stand still on a flat metal plate for 30 seconds, whereby the maximum height (cm) of the portion lifted from the metal plate, of the mold release film, is measured, and the measured value is adopted as the curl.

[7] A process for producing a semiconductor package having a semiconductor element and a resin sealed portion formed from a curable resin for sealing the semiconductor element, characterized by comprising

a step of disposing a mold release film as defined in any one of [1] to [6] on a surface of a mold which is to be in contact with a curable resin,

a step of disposing a substrate having a semiconductor element mounted thereon, in the mold, and filling a curable resin in a space in the mold, followed by curing to form a resin sealed portion, thereby to obtain a sealed body having the substrate, the semiconductor element and the resin sealed portion, and

a step of releasing the sealed body from the mold.

[8] The process for producing a semiconductor package according to [7], wherein in the step of obtaining a sealed body, a part of the semiconductor element is in direct contact with said release film.
[9] A process for producing a mold release film, comprising a step of dry laminating a first film for forming a first thermoplastic resin layer and a second film for forming a second thermoplastic resin layer, by using an adhesive, characterized in that

the storage elastic modulus E₁′ (MPa), the thickness T₁ (μm), the width W₁ (mm) and the tensile force F₁ (N) exerted thereon, at the dry lamination temperature t (° C.), of one of the first film and the second film, and the storage modulus E₂′ (MPa), the thickness T₂ (μm), the width W₂ (mm) and the tensile force F₂ (N) exerted thereon at the dry lamination temperature t (° C.), of the other film, satisfy the following formula (I),

0.8≦{(E₁′×T₁×W₁)×F₂}/{(E₂′×T₂×W₂)×F₁}≦1.2 (I)

wherein the storage elastic modulus E₁′ (180) and E₂′ (180) at 180° C. are from 10 to 300 MPa, the difference in storage elastic modulus at 25° C. i.e. |E₁′ (25)−E₂′ (25)| is at most 1,200 MPa, and T₁ and T₂ are, respectively, from 12 to 50 (μm).

### Advantageous Effects of Invention

The mold release film of the present invention is not easily electrically charged or curled, does not contaminate the mold and has excellent mold followability.

According to the process for producing a mold release film of the present invention, it is possible to produce a mold release film which is not easily electrically charged or curled, does not contaminate the mold and has excellent mold followability.

According to the process for producing a semiconductor package of the present invention, it is possible to prevent troubles caused by charging and discharging at the time of peeling of the mold release film, such as deposition of foreign matters on the charged mold release film, shape abnormalities of the semiconductor package or mold contamination associated therewith, breakage of the semiconductor chip due to the discharge from the mold release film, etc. Further, it is possible to carry out the adsorption of the mold release film satisfactorily.

### BRIEF DESCRIPTION OF DRAWINGS

FIG. 1 is a schematic cross-sectional view of a first embodiment of the mold release film of the present invention.

FIG. 2 is a schematic cross-sectional view of an example of the semiconductor package obtainable by the process for producing a semiconductor package of the present invention.

FIG. 3 is a schematic cross-sectional view of another example of the semiconductor package obtainable by the process for producing a semiconductor package of the present invention.

FIG. 4 is a schematic cross-sectional view showing a step (α3) in the first embodiment of the process for producing a semiconductor package of the present invention.

FIG. 5 is a schematic cross-sectional view showing a step (α4) in the first embodiment of the process for producing a semiconductor package of the present invention.

FIG. 6 is a schematic cross-sectional view showing a step (α4) in the first embodiment of the process for producing a semiconductor package of the present invention.

FIG. 7 is a schematic cross-sectional view of an example of the mold to be used in the second embodiment of the process for producing a semiconductor package of the present invention.

FIG. 8 is a schematic cross-sectional view showing a step (β1) in the second embodiment of the process for producing a semiconductor package of the present invention.

FIG. 9 is a schematic cross-sectional view showing a step (β2) in the second embodiment of the process for producing a semiconductor package of the present invention.

FIG. 10 is a schematic cross-sectional view showing a step (β3) in the second embodiment of the process for producing a semiconductor package of the present invention.

FIG. 11 is a schematic cross-sectional view showing a step (β4) in the second embodiment of the process for producing a semiconductor package of the present invention.

FIG. 12 is a schematic cross-sectional view showing a step (β5) in the second embodiment of the process for producing a semiconductor package of the present invention.

FIG. 13 is a schematic cross-sectional view showing a step (γ1) in the third embodiment of the process for producing a semiconductor package of the present invention.

FIG. 14 is a schematic cross-sectional view showing a step (γ3) in the third embodiment of the process for producing a semiconductor package of the present invention.

FIG. 15 is a schematic cross-sectional view showing a step (γ4) in the third embodiment of the process for producing a semiconductor package of the present invention.

FIG. 16 is a schematic cross-sectional view showing a step (γ5) in the third embodiment of the process for producing a semiconductor package of the present invention.

FIG. 17 is a view illustrating an apparatus for the followability test at 180° C., which was used in Examples.

### DESCRIPTION OF EMBODIMENTS

The following terms in this specification are used in the following meanings, respectively.

A “thermoplastic resin layer” is a layer made of a thermoplastic resin. To the thermoplastic resin, an additive such as an inorganic additive or an organic additive may be blended as the case requires.

“Units” in a resin means structural units (monomer units) that constitute the resin.

A “fluororesin” means a resin containing fluorine atoms in its structure.

The term “(meth)acrylic acid” is a general term for acrylic acid and methacrylic acid. The term “(meth)acrylate” is a general term for an acrylate and a methacrylate. The term “(meth)acryloyl” is a general term for acryloyl and methacryloyl.

The thickness of a thermoplastic resin layer is measured in accordance with ISO 4591: 1992 (JIS K7130: B1 method in 1999, Method of measuring the thickness of a sample taken from a plastic film or sheet by a mass method).

The storage elastic modulus E′ of a thermoplastic resin layer is measured in accordance with ISO 6721-4: 1994 (JIS K7244-4: 1999). The frequency shall be 10 Hz, the static force shall be 0.98N, and the dynamic displacement shall be 0.035%. The storage elastic modulus E′ measured at a temperature of t (° C.) is represented also by E′(t). E′ measured at a temperature of 25° C. and 180° C. by raising the temperature at a rate of 2° C. from 20° C., will be referred to as E′ (25) at 25° C. and E′ (180) at 180° C., respectively.

The arithmetic mean roughness (Ra) is an arithmetical mean roughness to be measured in accordance with JIS B0601: 2013 (ISO4287: 1997, Amd.1: 2009). The standard length Ir (cutoff value λc) for a roughness curve was set to be 0.8 mm.

A mold release film is a film to be used in the process for producing a semiconductor package by disposing a semiconductor element in a mold and sealing it with a curable resin to form a resin sealed portion and to be disposed on the surface of the mold which is to be in contact with the curable resin. The mold release film of the present invention is, for example, to be disposed to cover the cavity surface of a mold having a cavity of a shape corresponding to the shape of the resin sealed portion, at the time of forming the resin sealed portion of the semiconductor package, and as it is disposed between the formed resin sealed portion and the mold cavity surface, release of the obtained semiconductor package from the mold will be facilitated.

### [Mold Release Film in First Embodiment]

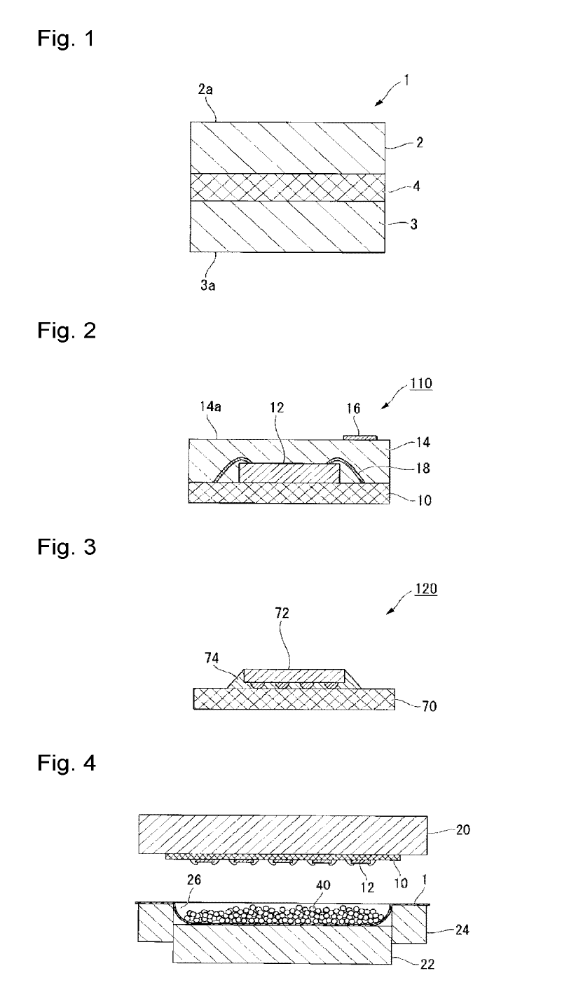

FIG. 1 is a schematic cross-sectional view illustrating a first embodiment of the mold release film of the present invention.

The mold release film 1 in the first embodiment comprises a first thermoplastic resin layer 2 to be in contact with the curable resin at the time of forming the resin sealed portion, a second thermoplastic resin layer 3 to be in contact with the mold at the time of forming the resin sealed portion and an interlayer 4 disposed therebetween.

At the time of producing a semiconductor package, the mold release film 1 is disposed so that the surface 2a on the first thermoplastic resin layer 2 side faces the mold cavity, and will be in contact with the curable resin at the time of forming the resin sealed portion. At that time, the surface 3a on the second thermoplastic resin layer 3 side is in close contact with the cavity surface of the mold. By curing the curable resin in this state, the resin sealed portion having a shape corresponding to the shape of the mold cavity will be formed.

### (First Thermoplastic Resin Layer)

The first thermoplastic resin layer 2 has a storage elastic modulus E′ (180) at 180° C. of from 10 to 300 MPa, particularly preferably from 30 to 150 MPa. 180° C. is the mold temperature at the time of usual molding.

When E′ (180) is at most the upper limit value in the above range, the mold release film is excellent in mold followability. At the time of sealing the semiconductor element, the mold release film is certainly in close contact with the cavity surface, and the mold shape is accurately transferred including its corners to the resin sealed portion. As a result, a highly accurate resin sealed portion will be formed, and the yield of the sealed semiconductor package will be high.

If the above E′ (180) exceeds the upper limit value in the above range, at the time of letting the mold release film follow the mold under vacuum, the mold followability of the mold release film tends to be insufficient. Therefore, in the transfer molding, at the time of clamping, the semiconductor element may be damaged by contact with the film which has failed to fully follow, or there may be a case where the corner portions of the sealed portion are absent. In the compression molding, because of the insufficient mold followability of the mold release film, the curable resin may overflow from the mold when the curable resin is sprinkled on the film, or there may be a case where the corner portions of the sealed portion are absent.

When E′ (180) is at least the lower limit value in the above range, the mold release film is less likely to be curled. Further, at the time of disposing the mold release film to cover the mold cavity while pulling the mold release film, because the mold release film is not too soft, the tension will be uniformly applied to the mold release film, whereby wrinkles are less likely to occur. As a result, there will be no transfer of wrinkles of the mold release film to the surface of the resin sealed portion, and the surface of the resin sealed portion will be excellent in appearance.

The storage elastic modulus E of the first thermoplastic resin layer 2 can be adjusted by the crystallinity of the thermoplastic resin constituting the first thermoplastic resin layer 2. Specifically, the lower the crystallinity of the thermoplastic resin, the lower the E′. The crystallinity of the thermoplastic resin can be adjusted by a known method. For example, in the case of an ethylene/tetrafluoroethylene copolymer, the crystallinity can be adjusted by the ratio of units based on tetrafluoroethylene and ethylene, or the type and content of units based on another monomer other than tetrafluoroethylene and ethylene.

The thickness of the first thermoplastic resin layer 2 is from 12 to 50 μm, preferably from 25 to 40 μm.

When the thickness of the first thermoplastic resin layer 2 is at least the lower limit value in the above range, the mold release film 1 is less likely to be curled. Further, it is easy to handle the mold release film 1, and at the time of disposing the mold release film 1 to cover the mold cavity while pulling the mold release film 1, wrinkles are less likely to be formed.

When the thickness of the first thermoplastic resin layer 2 is at most the upper limit value in the above range, the mold release film 1 is easily deformable and is excellent in mold followability.

The first thermoplastic resin layer 2 preferably has a mold releasing property whereby the curable resin cured (resin sealed portion) in a state being in contact with the first thermoplastic resin layer 2 side of the mold release film 1 can be easily peeled from the mold release film 1. Further, it preferably has heat resistance to withstand the mold temperature, typically from 150 to 180° C., during molding.

The thermoplastic resin (hereinafter referred to also as the thermoplastic resin I) constituting the first thermoplastic resin layer 2 is preferably at least one member selected from the group consisting of a fluororesin, a polystyrene and a polyolefin having a melting point of at least 200° C., from the viewpoint of the above-mentioned mold releasing property and heat resistance as well as the strength to withstand the flow and pressure of the curable resin, elongation at a high temperature, etc. One of these thermoplastic resins may be used alone, or two or more of them may be used in combination.

As the fluororesin, from the viewpoint of mold releasability and heat resistance, a fluoroolefin polymer is preferred. A fluoroolefin polymer is a polymer having units based on a fluoroolefin. The fluoroolefin may, for example, be tetrafluoroethylene, vinyl fluoride, vinylidene fluoride, trifluoroethylene, hexafluoropropylene, chlorotrifluoroethylene, etc. As the fluoroolefin, one type may be used alone, or two or more types may be used in combination.

The fluoroolefin polymer may, for example, be an ethylene/tetrafluoroethylene copolymer (hereinafter referred to also as ETFE), polytetrafluoroethylene, a perfluoro(alkyl vinyl ether)/tetrafluoroethylene copolymer, etc. As the fluoroolefin polymer, one type may be used alone, or two or more types may be used in combination.

As the polystyrene, from the viewpoint of the heat resistance and mold followability, syndiotactic polystyrene is preferred. The polystyrene may be a stretched one, and one type may be used alone, or two or more types may be used in combination.

As the polyolefin having a melting point of at least 200° C., from the viewpoint of the mold releasing property and mold followability, polymethylpentene is preferred. As the polyolefin, one type may be used alone, or two or more types may be used in combination.

The thermoplastic resin I is preferably at least one member selected from the group consisting of polymethylpentene and fluoroolefin polymers, and a fluoroolefin polymer is more preferred. Among these, from the viewpoint of large elongation at a high temperature, ETFE is particularly preferred. As ETFE, one type may be used alone, or two or more types may be used in combination.

ETFE is a copolymer comprising units based on tetrafluoroethylene (hereinafter referred to also as TFE) and units based on ethylene (hereinafter referred to also as E).

ETFE is preferably one having units based on TFE, units based on E and units based on a third monomer other than TFE and E. It is easy to adjust the crystallinity of ETFE i.e. the storage elastic modulus of the first thermoplastic resin layer 2, by the type and content of units based on the third monomer. Further, by having units based on the third monomer (especially a monomer having fluorine atoms), the tensile strength and elongation at a high temperature (especially at about 180° C.) will be improved.

As the third monomer, a monomer having fluorine atoms or a monomer having no fluorine atom may be mentioned.

As the monomer having fluorine atoms, the following monomers (a1)) to (a5) may be mentioned.

Monomer (a1): a fluoroolefin having at most 3 carbon atoms.

Monomer (a2): a perfluoroalkyl ethylene represented by X(CF₂)ₙCY═CH₂ (wherein X and Y are each independently a hydrogen atom or a fluorine atom, and n is an integer of from 2 to 8).

Monomer (a3): a fluorovinylether.

Monomer (a4): a functional group-containing fluorovinylether.

Monomer (a5): a fluorinated monomer having an aliphatic ring structure.

The monomer (a1)) may, for example, be a fluoroethylene (such as trifluoroethylene, vinylidene fluoride, vinyl fluoride or chlorotrifluoroethylene), or a fluoropropylene (such as hexafluoropropylene (hereinafter referred to also as HFP), or 2-hydropentafluoropropylene).

The monomer (a2) is preferably a monomer wherein n is from 2 to 6, particularly preferably a monomer wherein n is from 2 to 4. Also, a monomer wherein X is a fluorine atom, and Y is a hydrogen atom, i.e. a (perfluoroalkyl)ethylene, is particularly preferred.

As specific examples of the monomer (a2), the following compounds may be mentioned.

CF₃CF₂CH═CH₂,

CF₃CF₂CF₂CF₂CH═CH₂ ((perfluorobutyl)ethylene; hereinafter referred to also as PFBE),

CF₃CF₂CF₂CF₂CF═CH₂,

CF₂HCF₂CF₂CF═CH₂,

CF₂HCF₂CF₂CF₂CF═CH₂, etc.

As specific examples of the monomer (a3), the following compounds may be mentioned. Here, among the following, a monomer which is a diene, is a cyclo-polymerizable monomer.

CF₂═CFOCF₃,

CF₂═CFOCF₂CF₃,

CF₂═CF(CF₂)₂CF₃ (perfluoro(propyl vinyl ether); hereinafter referred to also as PPVE),

CF₂═CFOCF₂CF(CF₃)O(CF₂)₂CF₃,

CF₂═CFO(CF₂)₃O(CF₂)₂CF₃,

CF₂═CFO(CF₂CF(CF₃)O)₂(CF₂)₂CF₃,

CF₂═CFOCF₂CF(CF₃)O(CF₂)₂CF₃,

CF₂═CFOCF₂CF═CF₂,

CF₂═CFO(CF₂)₂CF═CF₂, etc.

As specific examples of the monomer (a4), the following compounds may be mentioned.

CF₂═CFO(CF₂)₃CO₂CH₃,

CF₂═CFOCF₂CF(CF₃)O(CF₂)₃CO₂CH₃,

CF₂═CFOCF₂CF(CF₃)O(CF₂)₂SO₂F, etc.

As specific examples of the monomer (a5), perfluoro(2,2-dimethyl-1,3-dioxole), 2,2,4-trifluoro-5-trifluoromethoxy-1,3-dioxole, perfluoro(2-methylene-4-methyl-1,3-dioxolane), etc. may be mentioned.

As the monomer having no fluorine atom, the following monomers (b1) to (b4) may be mentioned.

Monomer (b1): an olefin.

Monomer (b2): a vinyl ester.

Monomer (b3): a vinyl ether.

Monomer (b4): an unsaturated acid anhydride.

As specific examples of the monomer (b1), propylene, isobutene, etc. may be mentioned.

As specific examples of the monomer (b2), vinyl acetate, etc. may be mentioned.

As specific examples of the monomer (b3), ethyl vinyl ether, butyl vinyl ether, cyclohexyl vinyl ether, hydroxybutyl vinyl ether, etc. may be mentioned.

As specific examples of the monomer (b4), maleic anhydride, itaconic anhydride, citraconic anhydride, himic anhydride (5-norbornene-2,3-dicarboxylic acid anhydride), etc. may be mentioned.

As the third monomer, one type may be used alone, or two or more types may be used in combination.

The third monomer is preferably the monomer (a2), HFP, PPVE or vinyl acetate, more preferably HFP, PPVE, CF₃CF₂CH═CH₂ or PFBE, particularly preferably PFBE, in that adjustment of the crystallinity, i.e. the storage elastic modulus, will be thereby easy, and by having units based on a third monomer (especially a monomer having fluorine atoms), the tensile strength and elongation at a high temperature (particularly at about 180° C.) will be excellent.

That is, as ETFE, particularly preferred is a copolymer having units based on TFE, units based on E and units based on PFBE.

In ETFE, the molar ratio (TFE/E) of units based on TFE to units based on E is preferably from 80/20 to 40/60, more preferably from 70/30 to 45/55, particularly preferably from 65/35 to 50/50. When TFE/E is within the above range, the heat resistance and mechanical properties of ETFE will be excellent.

The proportion of units based on the third monomer in ETFE is preferably from 0.01 to 20 mol %, more preferably from 0.10 to 15 mol %, particularly preferably from 0.20 to 10 mol %, based on the total (100 mol %) of all units constituting ETFE. When the proportion of units based on the third monomer is within the above range, the heat resistance and mechanical properties of ETFE will be excellent.

In a case where the units based on the third monomer contain units based on PFBE, the proportion of units based on PFBE is preferably from 0.5 to 4.0 mol %, more preferably from 0.7 to 3.6 mol %, particularly preferably from 1.0 to 3.6 mol %, based on the total (100 mol %) of all units constituting ETFE. When the proportion of units based on PFBE is within the above range, it is possible to adjust the tensile elastic modulus of the mold release film at 180° C. to be within the above mentioned range. Further, the tensile strength and elongation at a high temperature (especially at about 180° C.) will be improved.

The melt flow rate (MFR) of ETFE is preferably from 2 to 40 g/10 min, more preferably from 5 to 30 g/10 min, particularly preferably from 10 to 20 g/10 min. When MFR is within the above range, the moldability of ETFE will be improved, and the mechanical properties of the mold release film will be excellent.

MFR of ETFE is a value as measured under a load of 49 N at 297° C. in accordance with ASTM D3159.

The first thermoplastic resin layer 2 may consist solely of a thermoplastic resin I, or may contain an additive such as an inorganic additive or an organic additive. The inorganic additive may, for example, be carbon black, silica, titanium oxide, cerium oxide, aluminum cobalt oxide, mica, zinc oxide, etc. The organic additive may, for example, be silicone oil, a metal soap, etc.

From the viewpoint of lowering the storage elastic modulus of the first thermoplastic resin layer 2 thereby to improve the mold followability, the first thermoplastic resin layer 2 preferably contains no inorganic additive.

The first thermoplastic resin layer 2 may have a single layer structure or a multilayer structure. From the viewpoint of the mold followability, tensile elongation, production cost, etc., a single layer structure is preferred.

From the viewpoint of excellent mold releasability, the first thermoplastic resin layer 2 has preferably a single layer structure made of a fluororesin, or a multilayer structure comprising a layer made of a fluororesin (hereinafter referred to also as a fluororesin layer) at least on the outermost layer on the surface 2a side, particularly preferably a single-layer structure made of a fluororesin.

The multilayer structure may, for example, be one comprising a plurality of fluororesin layers, or one comprising at least one fluororesin layer and at least one layer made of a resin other than a fluororesin (hereinafter referred to also as another layer) and having a fluororesin layer disposed at least on the outermost layer on the surface 2a side. Examples of the multi-layer structure containing said another layer include a two-layer structure in which a fluororesin layer and another layer are laminated in this order from the front surface 2a side, a three-layer structure in which a fluororesin layer, another layer and a fluororesin layer are laminated in this order from the surface 2a side, etc.

When the first thermoplastic resin layer 2 is made of a fluororesin, the mold release film 1 is excellent in mold releasability, sufficiently has heat resistance to withstand a mold temperature (typically from 150 to 180° C.) during molding, strength to withstand the flow or pressure of the curable resin, etc. and is also excellent in elongation at a high temperature. Especially when the first thermoplastic resin layer 2 has a single-layer structure, as compared with the case of a multilayer structure, the physical properties such as mold followability, tensile elongation, etc. will be excellent, suitability as a mold release film will be improved, and further the production costs tend to be less.

Of the first thermoplastic resin layer 2, the surface to be in contact with the curable resin at the time of forming the resin sealed portion, i.e. the first thermoplastic resin layer 2 side surface 2a of the mold release film 1 may be smooth or may have irregularities formed. From the viewpoint of the mold releasability, it is preferred that irregularities are formed.

The arithmetic mean roughness (Ra) of the surface 2a in the case of a smooth surface is preferably from 0.01 to 0.2 μm, particularly preferably from 0.05 to 0.1 μm.

Ra of the surface 2a in the case where irregularities are formed is preferably from 1.0 to 2.1 μm, particularly preferably from 1.2 to 1.9 μm.

The surface shape in the case where irregularities are formed, may be a shape in which a plurality of convexes and/or concaves are randomly distributed, or may be a shape in which a plurality of convexes and/or concaves are regularly arranged. Further, the shapes and sizes of the plurality of convexes and/or concaves may be the same or different.

The convexes may, for example, be elongated ridges extending on the surface of the mold release film, or projections scattered thereon. The concaves may, for example, be elongated grooves extending on the surface of the mold release film, or holes scattered thereon.

The shape of the ridges or grooves may be a straight line, curved line or bent line shape. On the surface of the mold release film, a plurality of ridges or grooves may be present in parallel or in stripes. Of ridges or grooves, the cross sectional shape in a direction perpendicular to the longitudinal direction may be polygonal such as triangular (V-shape), semi-circular or the like.

The shape of the protrusions or holes may be polygonal, such as triangular pyramid, square pyramid or hexagonal pyramid, conical, hemispherical, polyhedral, other various irregular shapes, etc.

### (Second Thermoplastic Resin Layer)

The storage elastic modulus E (180) at 180° C. and the thickness of the second thermoplastic resin layer 3, and preferred ranges thereof, are the same as the first thermoplastic resin layer 2.

E′ (180) and the thickness of the second thermoplastic resin layer 3 may, respectively, be the same as or different from E′ (180) and the thickness of the first thermoplastic resin layer 2.

However, the difference between E′ (25) at 25° C. of the first thermoplastic resin layer and E′ (25) at 25° C. of the second thermoplastic resin layer (i.e. |E′ (25) of the first thermoplastic resin layer—E′ (25) of the second thermoplastic resin layer|) is at most 1,200 MPa, particularly preferably at most 1,000 MPa. When the difference in E′ (25) is at most the lower limit value in the above range, it is possible to suppress curling. With a view to suppressing curling, the difference in thickness from the first thermoplastic resin layer 2 is preferably at most 20 μm.

From the viewpoint of the releasability of the mold release film 1 from the mold, the heat resistance to withstand the mold temperature (typically from 150 to 180° C.) at the time of molding, the strength to withstand the flow or pressure of the curable resin, the elongation at a high temperature, etc., the thermoplastic resin (hereinafter referred to also as the thermoplastic resin II) constituting the second thermoplastic resin layer 3 is preferably at least one member selected from the group consisting of a fluororesin, a polystyrene, a polyester, a polyamide, an ethylene/vinyl alcohol copolymer and a polyolefin having a melting point of at least 200° C. One of these thermoplastic resins may be used alone, or two or more of them may be used in combination.

The fluororesin, polystyrene and polyolefin having a melting point of at least 200° C., may be the same ones as mentioned above with respect to the thermoplastic resin I.

As the polyester, from the viewpoint of heat resistance and strength, polyethylene terephthalate (hereinafter referred to also as PET), easily moldable PET, polybutylene terephthalate (hereinafter referred to also as PBT), or polynaphthalene terephthalate is preferred.

The easily moldable PET is one having the moldability improved by copolymerizing another monomer in addition to ethylene glycol and terephthalic acid (or dimethyl terephthalate). Specifically, it is PET, of which the glass transition temperature Tg as measured by the following method is at most 105° C.

Tg is a temperature at which tan δ (E″/E′) being the ratio of the loss elastic modulus E″ to the storage elastic modulus E′ measured in accordance with ISO6721-4: 1994 (JIS K7244-4: 1999) takes a maximum value. Tg is measured by raising the temperature from 20° C. to 180° C. at a rate of 2° C./min. at a frequency of 10 Hz, a static force of 0.98N, and a dynamic displacement of 0.035%.

As the polyester, one type may be used alone, or two or more types may be used in combination.

As the polyamide, from the viewpoint of the heat resistance, strength and gas barrier properties, nylon 6 or nylon MXD6 is preferred. The polyamide may be a stretched one or one not stretched. As the polyamide, one type may be used alone, or two or more types may be used in combination.

As the thermoplastic resin II, among them, at least one member selected from the group consisting of polymethylpentene, a fluoroolefin polymer, easily moldable PET and PBT, is preferred, and at least one member selected from the group consisting of ETFE, easily moldable PET and PBT, is particularly preferred.

The second thermoplastic resin layer 3 may be one consisting solely of a thermoplastic resin II, or one having an additive such as an inorganic additive or an organic additive blended. The inorganic additive and the organic additive may be the same as those described above, respectively.

From the viewpoint of preventing contamination of the mold, or improving the mold followability by lowering the storage elastic modulus of the second thermoplastic resin layer 3, the second thermoplastic resin layer 3 preferably does not contain an inorganic additive.

The second thermoplastic resin layer 3 may have a single layer structure or a multilayer structure. From the viewpoint of the mold followability, tensile elongation, production costs, etc., it preferably has a single layer structure.

Of the second thermoplastic resin layer 3, the surface to be in contact with the mold at the time of forming the resin sealed portion, i.e. the second thermoplastic resin layer 3-side surface 3a of the mold release film 1, may be smooth or may have irregularities formed.

The arithmetic mean roughness (Ra) of the surface 3a in the case where it is smooth, is preferably from 0.01 to 0.2 μm, particularly preferably from 0.05 to 0.1 μm. Ra of the surface 3a in the case where irregularities are formed, is preferably from 1.5 to 2.1 μm, particularly preferably from 1.6 to 1.9 μm.

The surface shape in the case where irregularities are formed, may be a shape in which a plurality of convexes and/or concaves are randomly distributed, or may be a shape in which a plurality of convexes and/or concaves are regularly arranged. The shape and size of the plurality of convexes and/or concaves may be the same or different. Specific examples of the convexes, concaves, ridges, protrusions or holes are the same as those described above.

In a case where irregularities are formed on both of the surface 2a and the surface 3a, Ra and the surface shape of each surface may be the same or different.

### (Interlayer)

The interlayer 4 comprises a layer containing a polymeric antistatic agent (hereinafter referred to also as a polymeric antistatic layer). As it contains a polymeric antistatic agent, the polymeric antistatic layer has a low surface resistance and contributes to antistatic performance of the mold release film 1. The interlayer may further include other layers other than the polymeric antistatic layer.

The surface resistance of the inter layer 4 is preferably at most 10¹⁰Ω/□, particularly preferably at most 10⁹Ω/□ from the viewpoint of antistatic performance. When the surface resistance is at most 10¹⁰Ω/□, the antistatic performance is expressed at the first thermoplastic resin layer 2 side surface 2a of the mold release film 1. Therefore, during the production of a semiconductor package, even if a part of the semiconductor element is in direct contact with the mold release film 1, breakage of the semiconductor element due to charging and discharging of the mold release film can be sufficiently prevented.

The surface resistance of the interlayer 4 should better be as low as possible from the viewpoint of antistatic performance, and the lower limit is not particularly limited. The surface resistance value of the interlayer 4 tends to be small as the conductive performance of the polymeric antistatic agent becomes high, or as the content of the polymeric antistatic agent increases.

### <Polymeric Antistatic Layer>

As the polymeric antistatic agent, a polymer compound commonly known as an antistatic agent may be employed. For example, a cationic copolymer having a quaternary ammonium base in its side groups, an anionic compound containing polystyrene sulfonic acid, a compound having a polyalkylene oxide chain (a polyethylene oxide chain or a polypropylene oxide chain is preferred), a polyethylene glycol methacrylate copolymer, a polyether ester amide, a polyether amide imide, a polyether ester, a non-ionic polymer such as an ethylene oxide-epichlorohydrin copolymer, a π conjugated conductive polymer, etc. may be mentioned. One of these may be used alone, or two or more of them may be used in combination.

The quaternary ammonium salt in the copolymer having a quaternary ammonium base in its side groups, has the effect of imparting rapid dielectric polarization relaxation due to dielectric polarization and conductivity.

The above copolymer preferably has, in its side groups, a carboxyl group together with a quaternary ammonium base. When having a carboxyl group, the copolymer has crosslinkability and is capable of forming the interlayer 4 even alone. Further, when used in combination with an adhesive such as an urethane adhesive, it reacts with the adhesive to form a crosslinked structure, thereby to remarkably improve the adhesion, durability and other mechanical properties.

The copolymer may further have a hydroxy group in its side groups. The hydroxy group has an effect to enhance the adhesion by reacting with a functional group, for example, an isocyanate group in the adhesive.

The above copolymer can be obtained by copolymerizing a monomer having each functional group as mentioned above. Specific examples of the monomer having a quaternary ammonium base may be a dimethylaminoethyl acrylate quaternized product (containing, as a counter ion, an anion such as chloride, sulfate, sulfonate, alkyl sulfonate, etc.), etc. Specific examples of the monomer having a carboxyl group may be (meth)acrylic acid, (meth)acryloyloxyethyl succinic acid, phthalic acid, hexahydrophthalic acid, etc.

Other monomers other than these may be copolymerized. Such other monomers may, for example, be vinyl derivatives, such as alkyl (meth)acrylates, styrene, vinyl acetate, vinyl halides, olefins, etc.

The proportion of units having each functional group in the copolymer may be suitably set. The proportion of units having a quaternary ammonium base is preferably from 15 to 40 mol % based on the total of all units. When this proportion is at least 15 mol %, the antistatic effect will be excellent. If it exceeds 40 mol %, there is a possibility that the hydrophilicity of the copolymer becomes too high. The proportion of units having a carboxy group is preferably from 3 to 13 mol % based on the total of all units.

If the copolymer has a carboxy group in the side groups, to the copolymer, a crosslinking agent (curing agent) may be added. The crosslinking agent may, for example, be a bifunctional epoxy compound such as glycerol diglycidyl ether, a trifunctional epoxy compound such as trimethylolpropane triglycidyl ether, or a polyfunctional compound such as an ethyleneimine compound such as trimethylol propane triazinyl ether.

To the copolymer, as a ring-opening reaction catalyst of said bifunctional or trifunctional epoxy compound, an imidazole derivative such as 2-methylimidazole or 2-ethyl or 4-methylimidazole, or other amines may be added.

The π-conjugated conductive polymer is a conductive polymer having a main chain with π conjugation developed. As the π-conjugated conductive polymer, a known one may be used, and, for example polythiophene, polypyrrole, polyaniline, derivatives thereof, etc. may be mentioned.

As the polymeric antistatic agent, one produced by a known method may be used, or a commercial product may be used. For example, as a commercial product of a copolymer having a quaternary ammonium base and a carboxy group in the side groups, “Bondeip (BONDEIP, trade name)-PA100 main agent” manufactured by Konishi Co. may be mentioned.

As the polymeric antistatic layer, the following layers (1) to (4) may, for example, be mentioned.

Layer (1): the polymeric antistatic agent is one having a film-forming ability, and the layer is formed by wet-coating the polymeric antistatic agent, as it is, or as dissolved in a solvent, followed by drying as the case requires.

Layer (2): the polymeric antistatic agent is one having a film-forming ability and being meltable, and the layer is formed by melt-coating the polymeric antistatic agent.

Layer (3): the binder is one having a film-forming ability and being meltable, and the layer is formed by melt-coating a composition obtained by dispersing or dissolving a polymeric antistatic agent in the binder.

Layer (4): the binder is one having a film-forming ability, and the layer is formed by wet-coating a composition comprising said binder and a polymeric antistatic agent, as it is or as dissolved in a solvent, followed by drying as the case requires. Here, one falling under the layer (1) shall not belong to the layer (4).

In the layer (1), the polymeric antistatic agent having a film-forming ability, means that the polymeric antistatic agent is soluble in a solvent such as an organic solvent, and when the solution is wet-coated, followed by drying, a film is formed.

In the layer (2), the polymeric antistatic agent being meltable means that it is meltable by heating. In the layers (3) and (4), “having a film-forming ability” and “meltable” with respect to the binder, have the same meanings.

The polymeric antistatic agent in the layer (1) may be one having crosslinkability, or may be one having no crosslinkability. In the case where the polymer antistatic agent has crosslinkability, a crosslinking agent may be used in combination.

The polymeric antistatic agent having a film forming ability and crosslinkability, may, for example, be a copolymer having a quaternary ammonium base and a carboxy group in the side groups.

The cross-linking agent may be the same as one described above.

The thickness of the layer (1) is preferably from 0.01 to 1.0 μm, particularly preferably from 0.03 to 0.5 μm. If the thickness of the layer (1) is less than 0.01 μm, a sufficient antistatic effect may not be obtained, whereas if it exceeds 1.0 μm, when applying an adhesive layer thereon, the adhesion between the first thermoplastic resin layer 2 and the second thermoplastic resin layer 3 may deteriorate.

The polymeric antistatic agent in the layer (2) may, for example, be a polyolefin resin containing a surface active agent, carbon black, etc. Commercially available products may, for example, be Perekutoron HS (manufactured by Sanyo Chemical Industries, Ltd.), etc. The preferred range of the thickness of the layer (2) is the same as the preferred range of the thickness of the layer (1).

As the binder in the layer (3), a general-purpose thermoplastic resin may be mentioned. The thermoplastic resin is, in order to adhere during melt molding, preferably a resin having a functional group contributing to the adhesion. As such a functional group, a carbonyl group may, for example, be mentioned. The content of the polymeric antistatic agent in the layer (3) is preferably from 10 to 40 parts by mass, particularly preferably from 10 to 30 parts by mass, based on the total mass of the layer (3). The preferred range of the thickness of the layer (3) is the same as the preferred range of the thickness of the layer (1).

An example of a composition forming the layer (4) is an adhesive. The adhesive is meant for one which comprises a main agent and a curing agent and which is cured by heating, etc. to exhibit adhesion.

The adhesive may be a one-part adhesive, or may be a two-part adhesive.

The adhesive to form the layer (4) (hereinafter referred to also as the layer (4) forming adhesive) may, for example, be one having a polymeric antistatic agent added to an adhesive containing no polymeric antistatic agent.

The polymeric antistatic agent to be added to the adhesive may be one having a film forming ability, or one having no film-forming ability (e.g. a Tr-conjugated conductive polymer).

As the adhesive containing no polymeric antistatic agent, one known as an adhesive for dry lamination may be used. For example, a polyvinyl acetate-type adhesive; a polyacrylate-type adhesive consisting of a homopolymer or copolymer of an acrylic acid ester (ethyl acrylate, butyl acrylate, 2-ethylhexyl acrylate ester, etc.), or a copolymer of an acrylic acid ester and other monomers (methyl methacrylate, acrylonitrile, styrene, etc.); a cyanoacrylate-type adhesive; an ethylene copolymer-type adhesive consisting of e.g. a copolymer of ethylene and other monomers (vinyl acetate, ethyl acrylate, acrylic acid, methacrylic acid, etc.); a cellulose-type adhesive; a polyester-type adhesive; a polyamide-type adhesive; a polyimide-type adhesive; an amino resin-type adhesive consisting of e.g. an urea resin or a melamine resin; a phenol resin-type adhesive; an epoxy-type adhesive; a polyurethane-type adhesive obtained by crosslinking a polyol (a polyether polyol, a polyester polyol, etc.) with an isocyanate and/or isocyanurate; a rubber-type adhesive consisting of chloroprene rubber, nitrile rubber, styrene-butadiene rubber, etc.; a silicone adhesive; an inorganic adhesive made of an alkali metal silicate, a low melting point glass, etc.; or other adhesives may be used.

In the adhesive to form the layer (4), the content of the polymeric antistatic agent is preferably in such an amount that the surface resistance of the layer (4) would be preferably at most 10¹⁰Ω/□, particularly preferably at most 10⁹Ω/□.

From the viewpoint of the antistatic performance, the content of the polymeric antistatic agent in the layer (4) forming adhesive is preferably as high as possible, but in a case where the polymeric antistatic agent is a π-conjugated conductive polymer, and an interlayer 4 is to be formed by using, as the layer (4) forming adhesive, one having a π-conjugated conductive polymer added to an adhesive not containing a polymeric antistatic agent, if the content of the polymeric antistatic agent becomes large, the adhesion of the layer (4) tends to decrease, and the adhesion between the first thermoplastic resin layer 2 and the second thermoplastic resin layer 3 may become insufficient. Therefore, in such a case, the content of the polymeric antistatic agent in the layer (4) forming adhesive, is preferably at most 40 mass %, particularly preferably at most 30 mass %, based on the solid content of the resin as a binder. The lower limit is preferably 1 mass %, particularly preferably 5 mass %.

The thickness of the layer (4) is preferably from 0.2 to 5 μm, particularly preferably from 0.5 to 2 μm. When the thickness of the layer (4) is at least the lower limit value in the above range, the adhesion between the first thermoplastic resin layer and the second thermoplastic layer will be excellent. When the thickness is at most the upper limit value in the above range, the productivity will be excellent.

The polymeric antistatic layer which the interlayer (4) has, may be one layer or two or more layers. For example, it may have only one of the layers (1) to (4), or may have two or more of them.

As the polymeric antistatic layer, from the viewpoint of easy production, the layer (1) is preferred. The layer (1) may be used in combination with at least one of the layers (2) to (4).

### <Other Layers>

Other layers other than the polymeric antistatic layer may, for example, be a thermoplastic resin layer, a layer formed from an adhesive containing no polymeric antistatic agent (hereinafter referred to also as a non-antistatic adhesive layer), a gas barrier layer, etc. The thermoplastic resin layer may be the same one as the first thermoplastic resin layer 2 or the second thermoplastic resin layer 3. The adhesive in the non-antistatic adhesive layer may be the same as mentioned above. The gas barrier layer may, for example, be a metal layer, a metal vapor deposition layer, a metal oxide vapor deposition layer, etc.

### <Layer Structure of the Interlayer>

The interlayer 4 is preferably one having a polymeric antistatic layer and a non-antistatic adhesive layer, or one having the layer (4). When the interlayer 4 is in such a structure, the mold release film 1 can be produced by a dry lamination method.

As the preferred layer structure of the interlayer 4, the following (11) to (15) may, for example, be mentioned.

(11) A layer wherein sequentially from the first thermoplastic resin layer 2 side, any one of the layers (1) to (3) and a non-antistatic adhesive layer are laminated.

(12) A layer wherein sequentially from the first thermoplastic resin layer 2 side, the layer (4) and a non-antistatic adhesive layer are laminated.

(13) A layer consisting solely of one layer of the layer (4).

(14) A layer wherein sequentially from the first thermoplastic resin layer 2 side, the layer (4), a third thermoplastic resin layer and a non-antistatic adhesive layer are laminated.

(15) A layer wherein sequentially from the first thermoplastic resin layer 2 side, the layer (4), a third thermoplastic resin layer, a gas barrier layer and a non-antistatic adhesive layer are laminated.

Among the above, (11) or (13) is preferred, (11) is more preferred, and one wherein one of the layers (1) to (3) is the layer (1), is particularly preferred.

The thermoplastic resin to constitute the third thermoplastic resin layer may be the same resin as the thermoplastic resin II as described above. The thickness of the third thermoplastic resin layer is not particularly limited, but from 6 to 50 μm is preferred.

The thickness of the interlayer 4 is preferably from 0.1 to 55 μm, particularly preferably from 0.5 to 25 μm. When the thickness of the interlayer 4 is at least the lower limit value in the above range, the antistatic performance and the adhesion are sufficiently superior, and when it is at most the upper limit value, the mold followability will be excellent.

### (Thickness of Mold Release Film)

The thickness of the mold release film 1 is preferably from 25 to 100 μm, particularly preferably from 40 to 75 μm. When the thickness is at least the lower limit value in the above range, the mold release film is less likely to be curled. Further, it is easy to handle the mold release film, and when the mold release film is disposed to cover the mold cavity while pulling the mold release film, wrinkles are less likely to be formed. When the thickness is at most the upper limit value in the above range, the mold release film can be easily deformed, to improve the followability to the shape of the mold cavity, whereby the mold release film can be closely fit to the cavity surface, and a high quality resin sealed portion can be formed constantly. As the mold cavity is larger, the thickness of the mold release film 1 is preferably thinner within the above range. Further, as the mold is more complex with multiple cavities, it is preferably thinner within the above range.

### (Curl of Mold Release Film)

In the mold release film 1, the curl as measured by the following measuring method is preferably at most 1 cm, particularly preferably at most 0.5.

### (Method for Measuring the Curl)

At from 20 to 25° C., a square-shaped mold release film of 10 cm×10 cm is left to stand still on a flat metal plate for 30 seconds, whereby the maximum height (cm) of the portion lifted from the metal plate, of the mold release film, is measured, and the measured value is adopted as the curl.

If there is curl in the mold release film, the mold release film will not be well adsorbed to the mold. For supplying the mold release film to the mold at the time of production of a semiconductor package, it is common to employ a roll-to-roll system (a system in which a long mold release film in an wound up state, is unwound from an unwinding roll and supplied onto the mold in a state pulled by the unwinding roll and a wind-up roll), but recently, a pre-cut system (a system wherein a short length mold release film preliminarily cut to fit the mold is supplied to the mold) is also employed. If there is curl in the mold release film, especially in the case of the pre-cut system, there will be such a problem that the mold release film will not be well adsorbed on the mold.

When the curl is at most 1 cm, even in the case of the pre-cut system, the adsorption of the mold release film to the mold can be carried out satisfactorily.

The degree of the curl can be adjusted by the storage elastic modulus and thickness of the first thermoplastic resin layer 2 and the second thermoplastic resin layer 3, dry lamination conditions, etc.

### (Process for Producing Mold Release Film 1)

The mold release film 1 is preferably produced by a production process including a step of dry lamination of a first film to form a first thermoplastic resin layer 2 and a second film to form a second thermoplastic resin layer 3, by using an adhesive.

The dry lamination can be carried out by a known method.

For example, on one side of one of the first film and the second film, the adhesive is applied and dried, and the other film is overlaid thereon, followed by press-bonding by passing between a pair of rolls (lamination rolls) heated to a predetermined temperature (dry lamination temperature). Thus, it is possible to obtain a laminate wherein a first thermoplastic resin layer 2, an interlayer 4 having an adhesive layer and a second thermoplastic resin layer 3 are laminated in this order.

The adhesive may or may not contain a polymeric antistatic agent.

In a case where an adhesive containing no polymeric antistatic agent is to be used (in a case where the adhesive layer is a non-antistatic adhesive layer), before the step of dry lamination, a step of forming a polymeric antistatic layer on the surface (the interlayer 4 side) of either one or both of the first film and the second film, is carried out.

For example, on one side of one of the first film and the second film, a polymeric antistatic agent having a film-forming ability is applied and dried, then thereon, an adhesive containing no polymeric antistatic agent is applied and dried, and further thereon the other film is overlaid, followed by press-bonding by passing between a pair of rolls (lamination rolls) heated to a predetermined temperature (dry lamination temperature). Thus, it is possible to obtain a laminate wherein a first thermoplastic resin layer 2, a layer (1) and a non-antistatic adhesive layer, as the interlayer 4, and a second thermoplastic resin layer 3, are laminated in this order.

Before the step of dry lamination, and before or after the step of forming the polymeric antistatic layer, a step of forming other layers other than the non-antistatic adhesive layer and the polymeric antistatic layer may be carried out.

In a case where the adhesive containing the polymeric antistatic agent is to be used (in a case where the adhesive layer is the layer (4)), the step of forming a polymeric antistatic layer, or a step of forming other layers, may or may not be carried Out.

After the dry lamination, curing, cutting, etc. may be carried out as the case requires.

In the step of carrying out the dry lamination, the storage elastic modulus E₁′ (MPa), the thickness T₁ (μm), the width W₁ (mm) and the tensile force F₁ (N) exerted thereon, at the dry lamination temperature t (° C.), of one of the first film and the second film, and the storage modulus E₂′ (MPa), the thickness T₂ (μm), the width W₂ (mm) and the tensile force F₂ (N) exerted thereon at the dry lamination temperature t (° C.), of the other film, preferably satisfy the following formula (I), particularly preferably satisfy the following formula (II):

0.8≦{(E₁′×T₁×W₁)×F₂}/{(E₂′×T₂×W₂)×F₁}≦1.2 (I)

0.9≦{(E₁′×T₁×W₁)×F₂}/{(E₂′×T₂×W₂)×F₁}≦1.1 (II)

wherein the storage elastic modulus E₁′ (180) and E₂′ (180) at 180° C. are from 10 to 300 MPa, the difference in storage elastic modulus at 25° C. i.e. |E₁′ (25)−E₂′ (25)| is at most 1,200 MPa, and T₁ and T₂ are, respectively, from 12 to 50 (μm).

By carrying out the step of the dry lamination so as to satisfy the formula (I), the difference in the stress remaining in the two films during the dry lamination is minimized, whereby the mold release film to be obtained, will become one which is less likely to be curled.

As the film for dry lamination, a commercially available one may be used, or one produced by a known production method may be used. The film may be one subjected to surface treatment such as corona treatment, plasma treatment, primer coating treatment, etc.

As a method for producing a film is not particularly limited, and a known production method may be employed.

As a method for producing a thermoplastic resin film with both surfaces being smooth, a method may, for example, be mentioned in which melt-molding is conducted by an extruder equipped with a T die having a predetermined lip width.

A method for producing a film having irregularities formed on one side or on both sides may, for example, be a method of transferring irregularities of a base die to the surface of a film by thermal processing, and from the viewpoint of productivity, the following method (i) or (ii) is preferred. In the method (i) or (ii), by using a roll-form base die, continuous processing becomes possible, whereby the productivity of a film having irregularities formed, is remarkably improved.

(i) A method of passing a film between the base die roll and a pressing roll to continuously transfer irregularities formed on the surface of the base die roll onto the surface of the film.

(ii) A method of passing a thermoplastic resin extruded from the die of an extruder, between the base die roll and a pressing roll, to mold the thermoplastic resin into a film and at the same time, to continuously transfer irregularities formed on the surface of the base die roll onto the surface of the film-shaped thermoplastic resin.

In the method (i) or (ii), if, as the pressing roll, one having irregularities formed on its surface is used, it is possible to obtain a thermoplastic resin film having irregularities formed on both sides.

In the foregoing, the mold release film of the present invention has been described with reference to the first embodiment, but the present invention is not limited to the above embodiment. The respective constructions and their combinations in the above embodiment are one example, and additions, omissions, substitutions and other modifications of constructions can be made within a range not departing from the concept of the present invention.

### Advantageous Effects

The mold release film of the present invention is less likely to be electrically charged or to be curled, does not contaminate the mold, and is excellent in mold followability.

That is, the release film of the present invention has a polymeric antistatic layer, whereby it can exhibit antistatic performance even if an inorganic filler such as carbon black is not contained in the thermoplastic resin layers (the first thermoplastic resin layer, and the second thermoplastic resin layer). Therefore, during the production of semiconductor packages, it is possible to prevent troubles to be caused by charging and discharging at the time of peeling of the mold release film, such as deposition of foreign matters onto the electrically charged mold release film, breakage of a semiconductor chip due to the electrical discharge from the mold release film. Further, shape abnormalities of a semiconductor package or mold contamination due to foreign matters deposited onto the mold release film or detachment of the inorganic filler from the mold release film, tends to be less likely to occur. Further, the mold release film of the present invention is less likely to be curled and will be sufficiently provided with mold followability required in the production of semiconductor packages. Therefore, during the production of the semiconductor packages, adsorption of the mold release film to the mold can be conducted satisfactorily.

### [Semiconductor Package]

Semiconductor packages to be produced by the process for producing a semiconductor package of the present invention as described later, by using the mold release film of the present invention, include integrated circuits having semiconductor elements integrated, such as transistors, diodes, etc.; light-emitting diodes having a light emitting element, etc.

The package shape of the integrated circuit may be one which covers the entire integrated circuit or one which partially covers the integrated circuit (to expose a portion of the integrated circuit). As a specific example, BGA (Ball Grid Array), QFN (Quad Flat Non-leaded package) or SON (Small Outline Non-leaded package) may be mentioned.

As the semiconductor package, from the viewpoint of productivity, preferred is one to be produced via a batch sealing and singulation. For example, an integrated circuit wherein the sealing system is a MAP (Moldied Array Packaging) system or WL (Wafer Lebel packaging) system, may be mentioned.

FIG. 2 is a schematic cross-sectional view showing an example of a semiconductor package.

The semiconductor package 110 of this example comprises a substrate 10, a semiconductor chip (semiconductor element) 12 mounted on the substrate 10, a resin sealed portion 14 for sealing the semiconductor chip 12, and an ink layer 16 formed on the upper surface 14a of the resin sealed portion 14. The semiconductor chip 12 has a surface electrode (not shown), the substrate 10 has a substrate electrode (not shown) corresponding to the surface electrode of the semiconductor chip 12, and the surface electrode and the substrate electrode are electrically connected to each other by the bonding wires 18.

The thickness of the resin sealed portion 14 (the shortest distance from the semiconductor chip 12 mounting surface of the substrate 10 to the upper surface 14a of the resin sealed portion 14) is not particularly limited, but is preferably at least “the thickness of the semiconductor chip 12” and at most “the thickness of the semiconductor chip 12+1 mm”, particularly preferably at least “the thickness of the semiconductor chip 12” and at most “the thickness of the semiconductor chip 12+0.5 mm”.

FIG. 3 is a schematic cross-sectional view showing another example of a semiconductor package. The semiconductor package 120 of this example comprises a substrate 70, a semiconductor chip (semiconductor element) 72 mounted on the substrate 70, and an underfill (resin sealed portion) 74. The underfill 74 fills a gap between the substrate 20 and the main surface of the semiconductor chip 72 (the surface on the substrate 70 side), and the back surface of the semiconductor chip 72 (the surface opposite to the substrate 70 side) is exposed.

### [Process for Producing Semiconductor Package]

The process for producing a semiconductor package of the present invention is a process for producing a semiconductor package having a semiconductor element and a resin sealed portion formed from a curable resin for sealing the semiconductor element, characterized by comprising

a step of disposing the mold release film of the present invention on a surface of a mold which is to be in contact with the curable resin, so that the first thermoplastic resin layer side surface or the first mold release layer side surface faces the space in the mold,

a step of disposing a substrate having a semiconductor element mounted thereon, in the mold, and filling a curable resin in the space in the mold, followed by curing to form a resin sealed portion, thereby to obtain a sealed body having the substrate, the semiconductor element and the resin sealed portion, and

a step of releasing the sealed body from the mold.

For the process for producing a semiconductor package of the present invention, a known production method may be employed except for the use of the mold release film of the present invention.

For example, the method of forming the resin sealed portion may, for example, be a compression molding method or a transfer molding method, and as the apparatus to be used in such a case, a known compression molding apparatus or transfer molding apparatus may be employed. Also the production conditions may be the same as the conditions in the conventional processes for producing semiconductor packages.

### First Embodiment

As one embodiment of the process for producing a semiconductor package, a case wherein by using the above-described mold release film 1 as a mold release film, a semiconductor package 110 as shown in FIG. 2 is produced by a compression molding method, will be described in detail. The process for producing a semiconductor package in this embodiment has the following steps (α1) to (α7).

(α1)) A step of disposing the mold release film 1, so that the mold release film 1 covers the mold cavity and the surface 2a on the first thermoplastic resin layer 2 side, of the mold release film 1, faces the space in the cavity (so that the surface 3a on the second thermoplastic resin layer 3 side faces the cavity surface).

(α2) A step of vacuum-suctioning the mold release film 1 to the cavity surface side of the mold.

(α3) A step of filling a curable resin into the cavity.

(α4) A step of disposing a substrate 10 having a plurality of semiconductor chips 12 mounted thereon, at a predetermined position in the cavity, and collectively sealing the plurality of semiconductor chips 12 by the curable resin to form a resin sealed portion, thereby to obtain a collectively sealed body comprising the substrate 10, the plurality of semiconductor chips 12 mounted on the substrate 10 and the resin sealed portion collectively sealing the plurality of semiconductor chips 12.

(α5) A step of withdrawing the collectively sealed body from the mold.

(α6) A step of cutting the substrate 10 and the resin sealed portion of the collectively sealed body, so that the plurality of semiconductor chips 12 are separated, to obtain singulated sealed bodies each comprising the substrate 10, at least one semiconductor chip 12 mounted on the substrate 10 and a resin sealed portion 14 sealing the semiconductor chip 12.

(α7) A step of forming an ink layer 16 on the surface of the resin sealed portion 14 of the singulated sealed body by using an ink, to obtain a semiconductor package 1.

Mold:

As the mold in the first embodiment, one known as a mold to be used for a compression molding method may be employed, and for example, as shown in FIG. 4, a mold comprising a fixed upper mold 20, a cavity bottom member 22 and a frame-shaped movable lower mold 24 disposed at the periphery of the cavity bottom member 22, may be mentioned.

In the fixed upper mold 20, a vacuum vent (not shown) is formed to adsorb the substrate 10 to the fixed upper mold 20 by suctioning air between the substrate 10 and the fixed upper mold 20. Further, in the cavity bottom member 22, a vacuum vent (not shown) is formed to adsorb the mold release film 1 to the cavity bottom member 22 by suctioning air between the mold release film and the cavity bottom member 22.

In this mold, by the upper surface of the cavity bottom member 22 and the inner side surfaces of the movable lower mold 24, a cavity 26 having a shape corresponding to the shape of the resin sealed portion to be formed in step (α4) is formed. Hereinafter, the upper surface of the cavity bottom member 22 and the inner side surfaces of the movable lower mold 24 may be collectively referred to also as a cavity surface.

Step (α1):

On the movable lower mold 24, the mold release film 1 is disposed to cover the upper surface of the cavity bottom member 22. At that time, the mold release film 1 is disposed so that the second thermoplastic resin layer 3-side surface 3a faces downward (in the direction to the cavity bottom member 22).

The mold release film 1 is sent from an unwinding roll (not shown) and wound up by a wind-up roll (not shown). The mold release film 1 is pulled by the unwinding roll and the wind-up roll, and therefore is disposed in a stretched state on the movable lower mold 24.

Step (α.2):

Separately, by vacuum suctioning through a vacuum vent (not shown) of the cavity bottom member 22, the space between the upper surface of the cavity bottom member 22 and the mold release film 1, is evacuated, so that the mold release film is stretched, deformed and vacuum adsorbed on the upper surface of the cavity bottom member 22. Further, by tightening the frame-shaped movable lower mold 24 disposed at the periphery of the cavity bottom member 22, the mold release film 1 is pulled from all directions to be in tension.

Here, the mold release film 1 may not necessarily be in close contact with the cavity surface, depending upon the strength and thickness of the mold release film 1 in a high temperature environment, and the shape of the concave portion formed by the upper surface of the cavity bottom member 22 and the inner side surfaces of the movable lower mold 24. At the stage of vacuum suctioning in step (α2), as shown in FIG. 4, a void space may be slightly left between the mold release film 1 and the cavity surface.

Step (α3):

As shown in FIG. 4, a curable resin 40 is loaded in a suitable amount onto the mold release film 1 in the cavity 26 by an applicator (not shown). Further, separately, by vacuum suctioning through a vacuum vent (not shown) of the fixed upper mold 20, a substrate 10 having a plurality of semiconductor chips 12 mounted thereon, is vacuum-adsorbed on the lower surface of the fixed upper mold 20.

As the curable resin 40, various curable resins to be used in the production of semiconductor packages, etc. may be used. A thermosetting resin such as an epoxy resin or silicone resin is preferred, and an epoxy resin is particularly preferred.

As the epoxy resin, for example, SUMIKON EME G770H type Fver. GR, manufactured by Sumitomo Bakelite Co., Ltd., and T693/R4719-SP10, manufactured by Nagase ChemteX Corporation, may be mentioned. As commercial products of silicone resin, LPS-3412AJ and LPS-3412B, manufactured by Shin-Etsu Chemical Co., Ltd. may, for example, be mentioned.

The curable resin 40 may contain carbon black, fused silica, crystalline silica, alumina, silicon nitride, aluminum nitride, etc. Here, a case of filling solid one as the curable resin 40 has been described, but the present invention is not limited thereto, and a curable liquid resin may be filled.

Step (α4):

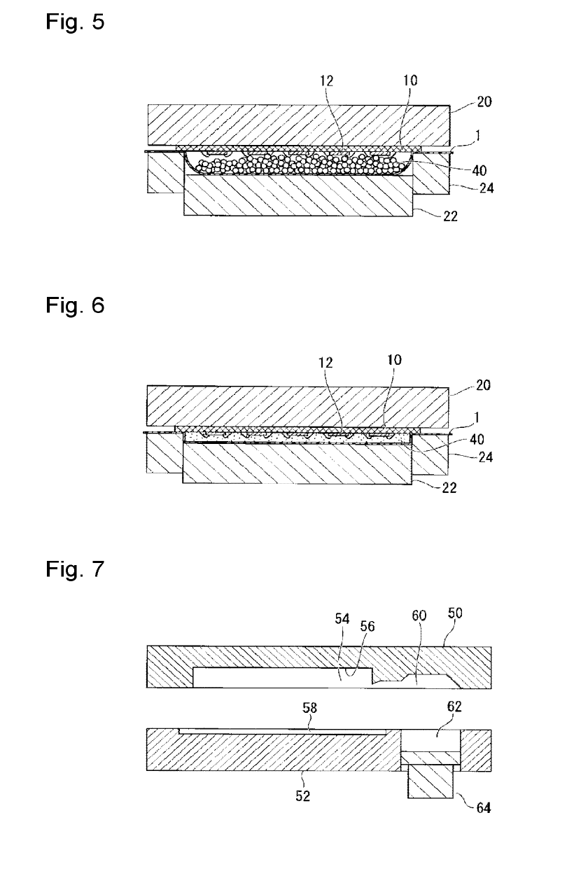

As shown in FIG. 5, in such a state that the curable resin 40 is filled on the mold release film 1 in the cavity 26, the cavity bottom member 22 and the movable lower mold 24 are raised and clamped to the fixed upper mold 20 for mold clamping. Then, as shown in FIG. 6, only the cavity bottom member 22 is raised and at the same time, the mold is heated to let the curable resin 40 be cured to form a resin sealed portion for collectively sealing the plurality of semiconductor chips 12.

In the step (α4), by the pressure at the time of raising the cavity bottom member 22, the curable resin 40 filled in the cavity 26 is further pushed to the cavity surface. The mold release film 1 is thereby stretched and deformed to be in close contact with the cavity surface. Therefore, the resin sealed portion having a shape corresponding to the shape of the cavity 26 will be formed.

The heating temperature of the mold, i.e. the heating temperature of the curable resin 40, is preferably from 100 to 185° C., particularly preferably from 140 to 175° C. When the heating temperature is at least the lower limit value in the above range, the productivity of the semiconductor package 110 is improved. When the heating temperature is at most the upper limit value in the above range, deterioration of the curable resin 40 is suppressed.

From the viewpoint of suppressing a change in the shape of the resin sealed portion 14 due to thermal expansion of the cured resin 40, when the protection of the semiconductor package 110 is particularly required, the heating is preferably conducted at the lowest possible temperature within the above range.

Step (α5):

The fixed upper mold 20, the cavity bottom member 22 and the movable lower mold 24 are mold-opened, and the collectively sealed body is taken out.

At the same time as releasing the collectively sealed body, the used portion of the mold release film 1 is sent to a wind-up roll (not shown), and the unused portion of the mold release film 1 is sent out from an unwinding roll (not shown). The thickness of the mold release film 1 at the time of transporting it from the unwinding roll to the wind-up roll is preferably at least 25 μm. If the thickness is less than 25 μm, wrinkling is likely to occur during the transportation of the mold release film 1. If wrinkles are formed in the mold release film 1, such wrinkles are likely to be transferred onto the resin sealed portion 14, thus leading to a defective product. When the thickness is at least 25 μm, it is possible to apply a sufficient tension to the mold release film 1, so as to prevent formation of wrinkles.

Step (α6):

The substrate 10 and the resin sealed portion of the collectively sealed body taken out from the mold, were cut (singulated) so that the plurality of semiconductor chips 12 are separated, to obtain singulated sealed bodies each comprising the substrate 10, at least one semiconductor chip 12 and a resin sealed portion 14 sealing the semiconductor chip 12.

Such singulation may be carried out by a known method, such as a dicing method. The dicing method is a method of cutting an object while rotating a dicing blade. As the dicing blade, typically a rotary blade (diamond cutter) having diamond powder sintered on the outer periphery of a disk, is used. Singulation by the dicing method can be carried out, for example, by a method wherein the collectively sealed body as an object to be cut, is fixed on the processing table via a jig, and the dicing blade is permitted to run in such a state that a space to insert the dicing blade is present between the jig and the cutting area of the object to be cut.

In the step (α6), after the step (cutting step) of cutting the collectively sealed body as described above, there may be included a foreign matter-removing step of moving the processing table while supplying a liquid towards the cutting object from a nozzle disposed at a position apart from the case which covers the dicing blade.

Step (α7):

On the upper surface 14a (the surface which has been in contact with the mold release film 1) of the resin sealed portion 14 of the singulated sealed body obtained in the step (α6), an ink is applied to form an ink layer 16 in order to display an optional information, thereby to obtain a semiconductor package 110.

The information to be displayed by the ink layer 16 is not particularly limited, and a serial number, information about the manufacturer, the type of components, etc. may be mentioned. The method for applying the ink is not particularly limited, and for example, various printing methods may be employed, such as an ink-jet method, screen printing, transfer from a rubber plate, etc.

The ink is not particularly limited and may be suitably selected from known inks. As a method for forming the ink layer 16, in view of a high curing speed, less bleeding on the package, and little positional displacement of the package since no hot air is applied, a method of using a photocurable ink is preferred wherein the ink is applied by an ink-jet method on the upper surface 14a of the resin sealed portion 14 and cured by irradiation with light.

As the photocurable ink, typically, one containing a polymerizable compound (monomer, oligomer, etc.) may be used. To the ink, as the case requires, a coloring material such as a pigment or a dye, a liquid medium (solvent or dispersant), a polymerization inhibitor, a photopolymerization initiator, other various additives, etc. may be added. Other additives may, for example, be a slip agent, a polymerization accelerator, a penetration enhancer, a wetting agent (humectant), a fixing agent, a fungicide, an antiseptic agent, an antioxidant, a radiation absorber, a chelating agent, a pH adjusting agent, a thickener, etc.

As the light to cure the photocurable ink, ultraviolet ray, visible ray, infrared ray, electron beam or radiation may, for example, be mentioned.

As the light source for ultraviolet ray, a germicidal lamp, an ultraviolet fluorescent lamp, a carbon arc, a xenon lamp, a high-pressure mercury lamp for copying, a medium-pressure or high-pressure mercury lamp, an ultrahigh-pressure mercury lamp, an electrodeless lamp, a metal halide lamp, an ultraviolet light emitting diode, an ultraviolet laser diode or natural light, may, for example, be mentioned.

Light irradiation may be carried out under normal pressure or under reduced pressure. Further, it may be carried out in air or in an inert gas atmosphere such as a nitrogen atmosphere or a carbon dioxide atmosphere.

### Second Embodiment

As another embodiment of the process for producing a semiconductor package, a case of producing the semiconductor package 110 shown in FIG. 2 by a transfer molding method by using the above-described mold release film 1 as a mold release film, will be described in detail.

The process for producing a semiconductor package in this embodiment has the following steps (β1) to (β7).

(β1) A step of disposing the mold release film 1, so that the mold release film 1 covers the mold cavity and the surface 2a on the first thermoplastic resin layer 2 side of the mold release film 1 faces the space in the cavity (so that the surface 3a on the second thermoplastic resin layer 3 side faces the cavity surface).

(β2) A step of vacuum-suctioning the mold release film 1 to the side of the cavity surface of the mold.

(β3) A step of disposing a substrate 10 having a plurality of semiconductor chips 12 mounted thereon at the predetermined position in the cavity.

(β4) A step of filling a curable resin into the cavity and collectively sealing the plurality of semiconductor chips 12 by the curable resin, to form a resin sealed portion thereby to obtain a collectively sealed body comprising the substrate 10, the plurality of semiconductor chips 12 mounted on the substrate 10, and the sealed portion collectively sealing the plurality of semiconductor chips 12.

(β5) A step of taking out the collectively sealed body from the mold.

(β6) A step of cutting the substrate 10 and the resin sealed portion of the collectively sealed body, so that the plurality of semiconductor chips 12 are separated, to obtain singulated sealed bodies each comprising the substrate 10, at least one semiconductor chip 12 mounted on the substrate 10, and a resin sealed portion 14 sealing the semiconductor chip 12.

(β7) A step of forming an ink layer by using an ink, on the surface of the resin sealed portion 14 of the singulated sealed body, to obtain a semiconductor package 1.

Mold:

As the mold in the second embodiment, one known as a mold for a transfer molding method may be used, and for example, as shown in FIG. 7, a mold having an upper mold 50 and a lower mold 52 may be mentioned. In the upper mold 50, a cavity 54 in a shape corresponding to the shape of the resin sealed portion 14 to be formed in the step (α4), and a concave resin introduction portion 60 for guiding a curable resin 40 to the cavity 54, are formed. In the lower mold 52, a substrate placement portion 58 to place the substrate 10 having the semiconductor chip 12 mounted thereon, and a resin placement portion 62 to place a curable resin 40, are formed. Further, in the resin placement portion 62, a plunger 64 for extruding a curable resin 40 to the resin introduction portion 60 of the upper mold 50, is provided.

Step (β1):

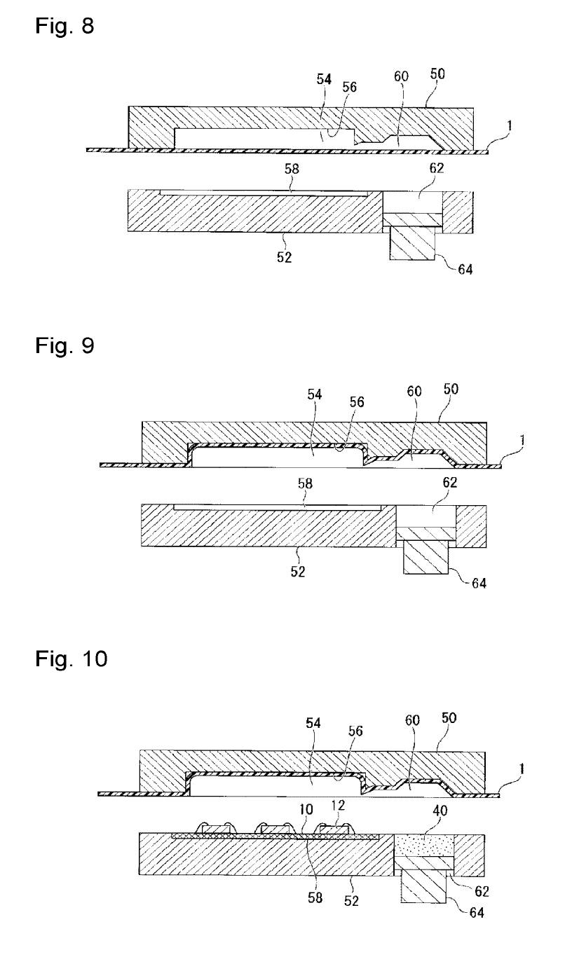

As shown in FIG. 8, the mold release film 1 is disposed to cover the cavity 54 of the upper die 50. The mold release film 1 is preferably disposed so as to cover the entire cavity 54 and the resin introduction portion 60. The mold release film 1 is pulled by the unwinding roll (not shown) and the wind-up roll (not shown), and therefore, it is disposed so as to cover the cavity 54 of the upper mold 50 in the stretched state.

Step (β2):

As shown in FIG. 9, by vacuum suctioning through a groove (not shown) formed outside of the cavity 54 of the upper mold 50, the space between the mold release film 1 and the cavity surface 56, and the space between the mold release film 1 and the inner wall of the resin introduction portion 60 are evacuated, so that the mold release film is stretched, deformed and vacuum adsorbed to the cavity surface 56 of the upper mold 50.

Here, the mold release film 1 may not necessarily be in close contact with the cavity surface 56, depending upon the strength or thickness of the mold release film 1 in a high temperature environment, or the shape of the cavity 54. As shown in FIG. 9, at the stage of vacuum suctioning in step (β2), a void space may slightly be left between the mod release film 1 and the cavity surface 56.

Step (β3):

As shown in FIG. 10, the substrate 10 having a plurality of semiconductor chips 12 mounted thereon is placed in the substrate placement portion 58, and the upper mold 50 and lower mold 52 are clamped so that the plurality of semiconductor chips 12 be placed at a predetermined position within the cavity 54. Further, on the plunger 64 of resin placement portion 62, a curable resin 40 is placed in advance. The curable resin 40 may be the same as the curable resin 40 mentioned in the process (a).

Step (β4):

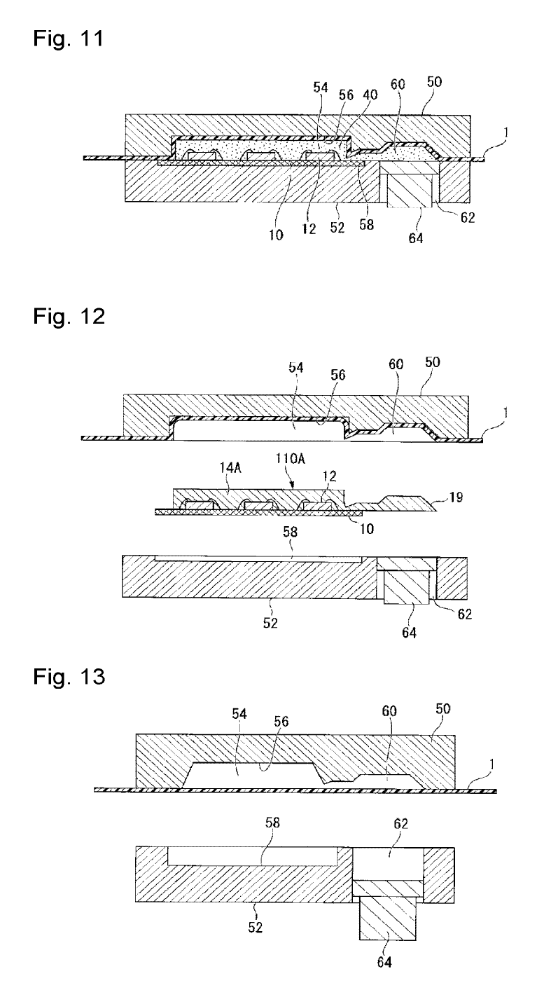

As shown in FIG. 11, the plunger 64 of the lower mold 52 is raised to fill the curable resin 40 into the cavity 54 through the resin introduction portion 60. Then, the mold is heated to cure the curable resin 40 thereby to seal the plurality of semiconductor chips 12 to form a resin sealed portion.

In the step (β4), as the curable resin 40 is filled into the cavity 54, the mold release film 1 is further pushed by the resin pressure to the cavity surface 56 side and stretched and deformed to be in close contact with the cavity surface 56. Therefore, a resin sealed portion 14 of a shape corresponding to the shape of the cavity 54 will be formed.

The mold heating temperature for curing the curable resin 40, i.e. the heating temperature of the curable resin 40, is preferably the same range as the temperature range in the process (α).

The resin pressure at the time of filling the curable resin 40 is preferably from 2 to 30 MPa, particularly preferably from 3 to 10 MPa. When the resin pressure is at least the lower limit value in the above range, a drawback such as inadequate filling of the curable resin 40 is less likely to occur. When the resin pressure is at most the upper limit value in the above range, it is easy to obtain an excellent quality semiconductor package 110. The resin pressure of the curable resin 40 can be adjusted by the plunger 64.

Step (β5):

As shown in FIG. 12, a collectively sealed body 110A comprising the substrate 10, the plurality of semiconductor chips 12 mounted on substrate 10 and the resin sealed portion 14A collectively sealing the plurality of semiconductor chips 12, is taken out from the mold. At that time, the cured product 19 having the curable resin 40 cured in the resin introduction portion 60, is taken out from the mold together with the collectively sealed body 110A, in such a state as adhered to the resin sealed portion 14A of the collectively sealed body 110A. Therefore, the cured product 19 adhered to the taken out collectively sealed body 110A is cut off, to obtain the collectively sealed body 110A.

Step (β6):

The substrate 10 and the resin sealed portion 14A of the collectively sealed body 110A obtained in the step (β5), are cut (singulated) so that the plurality of semiconductor chips 12 are separated, to obtain singulated sealed bodies each comprising the substrate 10, at least one semiconductor chip 12 and a resin sealed portion 14 sealing the semiconductor chip 12. Step (β6) can be carried out in the same manner as step (α6).

Step (β7):

To the upper surface 14a (the surface which has been in contact with the first surface of the mold release film 1) of the resin sealed portion 14 of the obtained singulated sealed body, an ink is applied to form an ink layer 16, in order to display any information, thereby to obtain a semiconductor package 110. Step (β7) can be carried out in the same manner as step (α7).

### Third Embodiment

As another embodiment of the process for producing a semiconductor package, a case of producing a semiconductor package 120 shown in FIG. 3 by a transfer molding method by using the above-described mold release film 1 as a mold release film, will be described in detail.

The process for producing a semiconductor package in this embodiment has the following steps (γ1) to (γ5).

(γ1) A step of disposing the mold release film 1, so as to cover the cavity of an upper mold of the mold having an upper mold and a lower mold and so that the surface 2a on the first thermoplastic resin layer 2 side of the mold release film 1 faces the space in the cavity (so that the second thermoplastic resin layer 3-side surface 3a faces the cavity surface of the upper mold).

(γ2) A step of vacuum-suctioning the mold release film 1 to the cavity surface side of the upper mold.

(γ3) A step of disposing a substrate 70 having a semiconductor chip 72 mounted thereon on the lower mold, and the upper mold and the lower mold are clamped, to bring the mold release film 1 to be in close contact with the back surface of the semiconductor chip 72 (the surface opposite to the substrate 70 side).

(γ4) A step of filling a curable resin into the cavity between the upper mold and the lower mold, to form the underfill 74, thereby to obtain a semiconductor package 120 (sealed body) comprising the substrate 70, the semiconductor chip 72 and the underfill 74.

(γ5) A step of taking out said semiconductor package 120 from the mold.

Mold:

As the mold in the third embodiment, it is possible to use the same one as the mold in the second embodiment.

Step (γ1):

As shown in FIG. 13, the mold release film 1 is disposed so as to cover the cavity 54 of the upper mold 50. Step (γ1) can be carried out in the same manner as step (β1).

Step (γ2):

By vacuum suctioning through a groove (not shown) formed outside of the cavity 54 of the upper mold 50, the space between the mold release film 1 and the cavity surface 56 and the space between the mold release film 1 and the inner wall of the resin introduction portion 60, are evacuated, to let the mold release film 1 be stretched, deformed and vacuum adsorbed to the cavity surface 56 of the upper mold 50. Step (γ2) can be carried out in the same manner as step (β2).

Step (γ3):

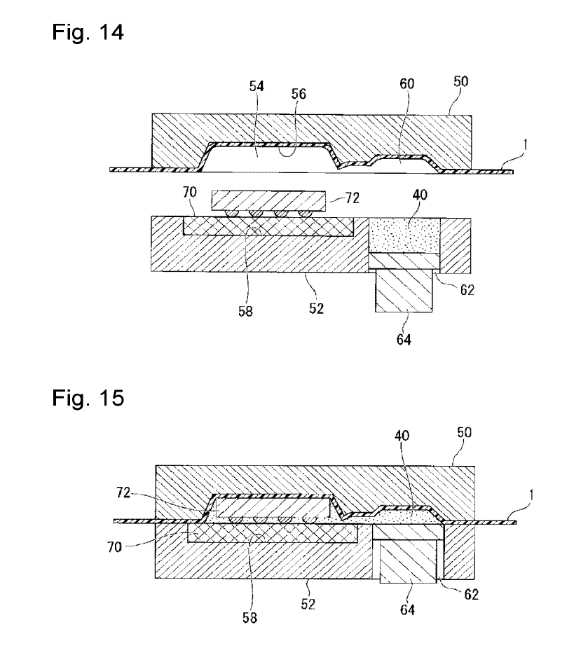

As shown in FIG. 14, a substrate 70 having the semiconductor chip 72 mounted thereon is placed on the substrate placement portion 58 of the lower mold 52.

Then, the upper mold 50 and the lower mold 52 are clamped, to dispose the semiconductor chip 12 at a predetermined position in the cavity 54, and at the same time, the mold release film is brought into close contact with the back surface of the semiconductor chip 72 (the surface opposite to the substrate 70 side). Further, on the plunger 64 of a resin placement portion 62, a curable resin 40 is placed in advance.

The curable resin 40 may be the same as the curable resin 40 mentioned in the process (α).

Step (γ4):

As shown in FIG. 15, the plunger 64 of the lower mold 52 is raised to fill the curable resin 40 into the cavity 54 through the resin introduction portion 60. Then, the mold is heated to cure the curable resin 40 to form an underfill 74. Step (γ4) can be carried out in the same manner as step (β4).

Step (γ5):

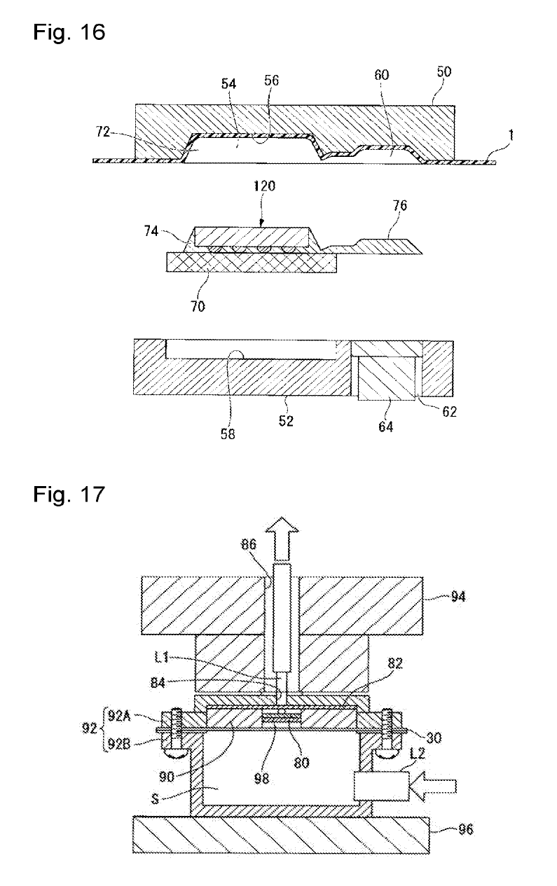

As shown in FIG. 16, the semiconductor package 120 comprising the substrate 70, the semiconductor chip 72 mounted on the substrate 70 and the underfill 74 sealing the side and bottom surfaces of the semiconductor chip 72, is taken out from the mold. At that time, the cured product 76 having the curable resin 40 cured in the resin introduction portion 60 is taken out from the mold together with the semiconductor package 12 in such a state as adhered to the under-fill 74 of the semiconductor package 12. Therefore, the cured product 76 adhered to the taken out semiconductor package 120 is cut off, to obtain the semiconductor package 120.

In this embodiment, in step (γ4), the curable resin 40 is filled in such a state that a portion (the back surface) of the semiconductor chip 72 is in direct contact with the mold release film 1. Thus, the curable resin will not be in contact with the portion of the semiconductor chip 72 which is in direct contact with the mold release film 1, whereby a semiconductor package 120 having a part of the semiconductor chip 72 exposed, will be obtained.

In the foregoing, the process for producing a semiconductor package of the present invention, has been described with reference to the first to third embodiments, but the present invention is not limited to the above embodiments. The respective constructions and their combinations, etc. in the above embodiments are exemplary, and additions, omissions, substitutions and other modifications can be made within a range not departing from the concept of the present invention.

For example, the first embodiment shows an example wherein step (α6) and step (α7) are conducted in this order after step (α5), but step (α6) and step (α7) may be carried out in the reverse order. That is, on the surface of the resin sealed portion of the collectively sealed body taken out from the mold, an ink layer may be formed by using an ink, and then, the substrate and the resin sealed portion of the collectively sealed body may be cut.

Similarly, the second embodiment shows an example wherein step (β6) and step (β7) are conducted in this order after step (β5), but step (β6) and step (β7) may be carried out in the reverse order. That is, on the surface of the resin sealed portion of the collectively sealed body taken out from the mold, an ink layer may be formed by using an ink, and then, the substrate and the resin sealed portion of the collectively sealed body may be cut.

The timing of peeling off the resin sealed portion from the mold release film is not limited to at the time of taking out the resin sealed portion from the mold, and the resin sealed portion may be taken out together with the mold release film from the mold, and then the mold release film may be peeled off from the resin sealed portion.

The distances between respective adjacent ones of the collectively sealed plurality of semiconductor chips 12 may be uniform or may not be uniform. From such viewpoints that sealing can be uniformly done, and a load will be uniformly exerted to the plurality of semiconductor chips 12, respectively, (i.e. the load will be minimized), it is preferred to equalize the distances between respective adjacent ones of the plurality of semiconductor chips 12.

Further, semiconductor packages to be produced by the process for producing a semiconductor package of the present invention are not limited to the semiconductor packages 110 and 120.

Depending on the semiconductor package to be produced, steps (α6) to (α7) in the first embodiment, and steps (β6) to (β7) in the second embodiment may not be conducted. For example, the shape of the resin sealed portion is not limited to those shown in FIGS. 2 and 3, and there may be difference in level, etc. Semiconductor elements to be sealed in the resin sealed portion may be one or more. The ink layer is not essential.

In the case of producing a light-emitting diode as a semiconductor package, a resin sealed portion will function also as a lens unit, and usually, no ink layer is formed on the surface of the resin sealed portion. In the case of such a lens part, as the shape of the resin sealed portion, a variety of lens shape may be employed, including approximately hemispherical, bullet-shaped, Fresnel lens type, semi-cylindrical, substantially hemispherical lens array type, etc.

### EXAMPLES

Now, the present invention will be described in detail with reference to Examples. However, the present invention is not limited by the following description. Among the following Ex. 1 to 13, Ex. 1 to 9 are Examples of the present invention, and Ex.10 to 13 are Comparative Examples. The materials and evaluation methods used in Examples are shown below.

### [Materials Used]

### <Thermoplastic Resins>

ETFE (1): copolymer of tetrafluoroethylene/ethylene/PFBE=52.5/46.3/1.2 (molar ratio) (MFR: 12 g/10 min.) obtained in Production Example 1 as described below.

ETFE (2): copolymer of tetrafluoroethylene/ethylene/PFBE=56.3/40.2/3.5 (molar ratio) (MFR: 12.5 g/10 min.) obtained in Production Example 2 as described below.

PBT: polybutylene terephthalate, “NOVADURAN 5020” (manufactured by Mitsubishi Engineering Plastics Corporation).

Polymethylpentene: “TPX MX004” (manufactured by Mitsui Chemicals, Inc.).

### Production Example 1

### Production of ETFE (1)

A polymerization tank having an inner volume of 1.3 L and equipped with a stirrer, was deaerated; 881.9 g of 1-hydrotridecafluorohexane, 335.5 g of 1,3-dichloro-1, 1,2,2,3-pentafluoropropane (trade name “AK225cb” manufactured by Asahi Glass Co., Ltd., hereinafter referred to also as AK225cb), and 7.0 g of CH₂═CHCF₂CF₂CF₂CF₃ (PFBE) were charged; 165.2 g of TFE and 9.8 g of ethylene (hereinafter referred to also as E) were injected; the inside of the polymerization tank was heated to 66° C.; and 7.7 mL of a 1 mass % AK225cb solution of tertiary butyl peroxypivalate (hereinafter referred to as PBPV) was charged as a polymerization initiator solution, to start the polymerization.

In order to maintain the pressure to be constant during the polymerization, a monomer mixture gas in a molar ratio of TFE/E=54/46, was continuously charged. Further, in accordance with the charge of the monomer mixture gas, PFBE in an amount corresponding to 1.4 mol % to the total number of moles of TFE and E, was continuously charged. After 2.9 hours from the initiation of the polymerization, at the time when 100 g of the monomer mixture gas was charged, the internal temperature of the polymerization tank was lowered to room temperature, and at the same time, the pressure of the polymerization tank was purged to normal pressure.

Thereafter, the obtained slurry was suction filtered through a glass filter, and the solid content was recovered and dried at 150° C. for 15 hours, to obtain 105 g of ETFE (1).

### Production Example 2

### Production of ETFE (2)

90 g of ETFE (2) was obtained in the same manner as in Production Example 1, except that the inner volume of the polymerization tank was changed to 1.2 L, the amount of 1-hydrotridecafluorohexane to be charged before starting the polymerization, was changed to 0 g from 881.9 g, the amount of AK225cb was changed to 291.6 g from 335.5 g, the amount of PFBE was changed from 7.0 g to 16.0 g, the amount of TFE was changed to 186.6 g from 165.2 g, the amount of E was changed to 6.4 g from 9.8 g, the amount of 1 mass % AK225cb solution of PBPV was changed to 5.3 mL from 5.8 mL, the molar ratio of TFE/E in the monomer mixture gas continuously charged during the polymerization was changed from 54/46 to 58/42, the amount of PFBE (relative to the total number of moles of TFE and E) was changed from 0.8 mol % to 3.6 mol %, and after 3 hours from the initiation of the polymerization, at the time when 90 g of the monomer mixture gas was charged, the internal temperature of the polymerization tank was lowered to room temperature.

### <Thermoplastic Resin Films>

ETFE film (1-1): Thickness 30 μm. One side has irregularities with Ra being 1.5 and the other side is smooth with Ra being 0.1. ETFE film (1-1) was prepared by the following procedure.

ETFE (1) was melt-extruded at 320° C. by an extruder having the lip opening adjusted so that the thickness of the film would be 30 μm. By adjusting the base die roll, the film-forming speed and the nip pressure, the ETFE film was produced.

ETFE film (1-2): Thickness 25 μm. Both sides are smooth with Ra of both sides being 0.1. ETFE film (1-2) was prepared in the same manner as ETFE film (1-1) except that the base die roll, the film forming speed and the nip pressure condition were adjusted.

ETFE film (2-1): Thickness 25 μm. Both sides are smooth with Ra of both sides being 0.1. ETFE film (2-1) was prepared in the same manner as ETFE film (1-2) except that ETFE (2) was used in place of ETFE (1), and the extrusion temperature was changed to 300° C.

ETFE film (1-3): Thickness 12 μm. Both sides are smooth with Ra of both sides being 0.1. ETFE film (1-3) was produced in the same manner as ETFE film (1-2) except that the conditions were adjusted so that the thickness would be 12 μm.

ETFE film (1-4): Thickness 50 μm. Both sides are smooth with Ra of both sides being 0.1. It was produced in the same manner as ETFE film (1-2) except that the conditions were adjusted so that the thickness would be 50 μm.

Further, each of the films was corona-treated so that the wetting tension based on ISO8296: 1987 (JIS K6768 1999) would be at least 40 mN/m.

PBT film (1-1): Thickness 25 μm. One side has irregularities with Ra being 0.8, and the other side is smooth with Ra being 0.1. PBT film (1-1) was prepared by the following procedure.

Polybutylene terephthalate resin “NOVADURAN 5020” (manufactured by Mitsubishi Engineering-Plastics Corporation) was melt-extruded at 280° C. by an extruder having the lip opening adjusted so that the thickness would be 25 μm. By adjusting the base die roll, the film-forming speed and the nip pressure, the PBT film was produced.

PBT film (1-2): Thickness 50 μm. There are irregularities on both sides, and Ra of both sides is 1.5. PBT film (1-2) was prepared in the same manner as PBT film (1-1) except that the base die roll, the film-forming speed and the nip pressure condition were adjusted.

TPX film (1-1): Thickness 25 μm. One side has irregularities with Ra being 0.8, and the other side is smooth with Ra being 0.1. TPX film (1-1) was prepared by the following procedure.

Polymethylpentene resin “TPX MX004” (manufactured by Mitsubishi Engineering-Plastics Corporation) was melt extruded at 280° C. by an extruder having the lip opening adjusted so that the thickness would be 25 μm. By adjusting the base die roll, the film-forming speed and the nip pressure, the TPX film was produced. It was corona-treated so that the wetting tension based on ISO8296: 1987 (JIS K6768 1999) would be at least 40 mN/m.

PET film (1-1): Thickness 25 μm. “Tetoron G2 25 μm” (manufactured by Teijin DuPont Films) was used. Both sides are flat with Ra of both sides being 0.2.

PET film (1-2): Thickness 50 μm. “Tetoron G2 50 μm” (manufactured by Teijin DuPont Co., Ltd.) was used. Both sides are flat with Ra of both sides being 0.2.

Polyamide film (1-1): Thickness 25 μm. “Diamiron C-Z” (manufactured by Mitsubishi Plastics Co., Ltd.) was used. Both sides are flat with Ra of both sides being 0.1.

ETFE (3 parts by mass of carbon black kneaded) film (1-1): Thickness 50 μm. There are irregularities on both sides, and Ra of both sides is 1.5. ETFE (3 parts by mass of carbon black kneaded) film (1-1) was prepared by the following procedure.

To 100 parts by mass of pellets of ETFE (1), 3 parts by mass of carbon black “DENKA BLACK granules” (manufactured by Denki Kagaku Kogyo KK) was added, followed by kneading by a twin screw extruder at 320° C. to obtain compound pellets. The pellets were melt-extruded by an extruder at a 320° C., to produce the ETFE (3 parts by weight of carbon black kneaded) film.

### <Other Materials>

Bondeip (BONDEIP, trade name)-PA100: Bondeip (trade name) PA100 main agent, Bondeip (trade name) PA100 curing agent (manufactured by Konishi Co., Ltd.).

Conductive polymer A: Polypyrrole dispersion “CORERON YE” (manufactured by Kaken Sangyo Co., Ltd.).

Adhesive composition 1: Polyester polyol “CRISVON NT-258” (manufactured by DIC Corporation) as a main agent, and hexamethylene diisocyanate “Coronate 2096” (manufactured by Nippon Polyurethane Industry Co., Ltd.) as a curing agent.

Pelestat (trade name) NC6321: resin having a polyethylene oxide chain.

### [Production Method of Mold Release Film]

### (Dry Lamination)

In all Ex., dry lamination was carried out by applying each coating solution to a substrate (a film corresponding to the second thermoplastic resin layer) by gravure coating under conditions of substrate width: 1,000 mm, conveying speed: 20 m/min., drying temperature: 80 to 100° C., laminate roll temperature: 25° C. and pressure: 3.5 MPa.

### [Evaluation Methods]

### (Peel Strength at 180° C.)

Among the mold release films produced in the respective Ex., with respect to a mold release film having a film construction wherein two films (a first thermoplastic resin layer and a second thermoplastic resin layer) were dry-laminated, a 180 degree peel test was conducted as follows in accordance with JIS K6854-2: 1999, whereby the peel strength (N/cm) at 180° C. between the two thermoplastic resin films was measured.

(a) The prepared mold release film was cut into 25 mm in width×15 cm in length to obtain an evaluation sample.

(b) In a constant temperature tank heated to 180° C., using a tensile testing machine (RTC-1310A manufactured by Orientec Co.), the second thermoplastic resin layer of the evaluation sample was gripped by a lower jaw, the first thermoplastic resin layer was gripped by the upper jaw, and the peel strength at an angle of 180 degrees was measured by moving the upper jaw upwards at a rate of 100 mm/min.

(c) In the force (N)-gripping movement distance curve, an average value of peel strength (N/cm) from the gripping movement distance of from 30 mm to 100 mm was obtained.

(d) An average value of the peel strengths of five evaluation samples prepared from the same mold release film, was obtained. That value was taken as the peel strength at 180° C. of the mold release film.

### (Surface Resistance of Antistatic Layer)

In each Ex., after forming an antistatic layer on the second thermoplastic resin layer, without laminating the first thermoplastic resin layer, the surface resistance was measured in accordance with IEC60093. For Ex. 7 wherein no antistatic layer was formed, the surface resistance of the mold release film was directly measured. The measurement environment was at 23° C. under 50% RH.

### (Elastic Modulus)

The storage elastic modulus E′ (25) at 25° C. and the storage elastic modulus E′ (180) at 180° C. of films corresponding to the respective layers of the first thermoplastic resin layer and the second thermoplastic resin layers were measured by the following procedure.

Using a dynamic viscoelasticity measuring apparatus Solid L-1 (manufactured by Toyo Seiki Co., Ltd.), the storage elastic modulus E′ was measured based on ISO 6721-4: 1994 (JIS K7244-4: 1999). E′ measured at temperatures of 25° C. and 180° C. by setting the frequency to be 10 Hz, the static force to be 0.98N and the dynamic displacement to be 0.035%, and raising the temperature from 20° C. at a rate of 2° C. /min., were adopted as the storage elastic modulus E′ (25) at 25° C. and the storage elastic modulus E′ (180) at 180° C., respectively.

### (Ash Adhesion Test)

On a metal substrate, a sponge having a thickness of 1 cm, a square shape of 10 cm×10 cm and a square hole of 8 cm×8 cm opened at the center, was placed, then 1 g of cigarette ash was put at the central part of the hole, and a mold release film was placed on the sponge so that the first thermoplastic resin layer side faced downward and left to stand at a temperature of from 23 to 26° C. under a humidity of 50±5% RH for 1 minute. Then, the presence or absence of adhesion of the ash to the mold release film was visually observed. The results were evaluated in accordance with the following standards. The less the adhesion of the ash, the less likely the electrical charging of the mold release film.

◯ (good): The ash does not adhere at all.

x (bad): The ash adheres.

### (180° C. Followability Test)

The apparatus shown in FIG. 17 comprises a stainless steel frame member (thickness: 3 mm) 90 having a square hole of 11 mm×11 mm at the center, a jig 92 having a space S capable of housing the frame member 90 therein, a weight 94 disposed on the jig 92, and a hot plate 96 disposed below the jig 92.

The jig 92 comprises an upper member 92A and a lower member 92B. It is so designed that by sandwiching a mold release film 30 to be evaluated, between the upper member 92A and the lower member 92B, and placing the weight 94, the mold release film 30 is fixed, and an airtight space S is formed. At that time, the frame member 90 is, in a state in which a stainless steel frame (10.5 mm×10.5 mm) 98 and a stainless steel mesh (10.5 mm×10.5 mm) 80 are accommodated in the hole, housed in the upper member 92A side of the jig 92, and in contact with the mold release film 30.

At the top surface of the upper member 92A, an exhaust port 84 is formed, and on the opening surface of the space S side of the exhaust port 84, a stainless steel mesh (10.5 mm×10.5 mm) 82 is disposed. Further, at the position corresponding to the exhaust port 84, of the weight 94, a through hole 86 is formed, and a pipe L1 is connected to the exhaust port 84 through the through hole 86. To the pipe L1, a vacuum pump (not shown) is connected, so that it is possible to evacuate the space S in the jig 92 by actuating the vacuum pump. To the lower member 92B, a pipe L2 is connected so that a compressed air can be supplied to the space S in the jig 92 via the pipe L2.

In this apparatus, there is a slight gap between the inner surface of the hole of the frame member 90 and the outer edge of each of the mesh 80 and the frame 98, so that the mesh 80 and frame 98 are movable in the vertical direction in the hole of the frame member 90. Further, the air between the mold release film 30 and the frame 98 can be vacuum-suctioned by a vacuum pump through the gap, so that the space between the lower surface of the frame member 90 and the mold release film 30 can be evacuated.

By evacuating the space between the lower surface of the frame member 90 and the mold release film 30 under reduced pressure, and, as the case requires, by supplying a compressed air from the pipe L2 into the space S, it is possible to stretch the mold release film 30 so that it will be in close contact with the inner circumferential surface of the hole of the frame member 90 and with the lower surface of the frame 98.

In this apparatus, by changing the thickness of the frame 98 to be put into the hole of the frame member 90, it is possible to change the depth for followability i.e. the distance between the lower surface of the frame material 90 (the surface with which the mold release film 30 is in contact) and the lower surface of the frame 98 (the surface on the mold release film 30 side).

In the test, firstly, using as the frame 98, one having a depth for followability of 0.8 mm, the mold release film 30 was fixed to a jig 92 so that it was in close contact with the frame member 90. At that time, the mold release film 30 was disposed so that the surface on the second thermoplastic resin layer side faced upward (the frame member 90 side). Then, after heating the entire jig 92 to 180° C. by a hot plate 96, the air between the frame 98 and the mold release film 30 was suctioned by operating the vacuum pump. Further, compressed air (0.5 MPa) was supplied into the space S from the pipe L2, to let the mold release film 30 follow the frame member 90 and the frame 98. That state was maintained for 3 minutes, and the vacuum degree of the vacuum pump was checked, whereupon it was visually confirmed whether or not the mold release film 30 followed the corner (the corner formed by the inner peripheral surface of the hole of the frame member 90 and the lower surface of the frame 98). Thereafter, the operation of the vacuum pump and the supply of compressed air were stopped, and the mold release film 30 was promptly taken out. The taken out mold release film 30 was visually observed to confirm whether or not peeling between the layers was observed. The results were evaluated in accordance with the following standards.

◯ (good): The mold release film completely followed the mold, and no peeling between the layers was observed.

Δ (acceptable): The mold release film followed the mold, but peeling was observed between the layers of the mold release film.

x (bad): The mold release film was not fit to follow the mold.

### (Curl Test)

The curl of the mold release film was measured by the following procedure.

At 25° C., a mold release film of a square shape of 10 cm×10 cm was left to stand for 30 seconds on a flat metal plate, whereby the maximum height (cm) of the portion lifted from the metal plate, of the mold release film, was measured, and the measured value was adopted as the curl. The results were evaluated in accordance with the following standards.

◯ (good): The curl was less than 1 cm.

x (bad): The curl was at least 1 cm.

### (Mold Contamination)

A non-molded substrate was set on the lower mold for transfer molding in an 180° C. environment, and after vacuum-adsorption of the mold release film to the upper mold, the upper and lower molds were closed, and using a semiconductor molding epoxy resin, transfer molding was conducted under 7 MPa for 180 seconds. Under the above conditions, mold shot was repeated 1,000 times. Contamination of the mold at that time was checked with the naked eye. The results were evaluated in accordance with the following standards.

◯ (good): No contamination of the mold was observed.

x (bad): Contamination of the mold was observed.

### [Ex. 1]

As the first thermoplastic resin layer, ETFE film (1-1), and as the second thermoplastic resin layer, ETFE film (1-1), were used.

Bondeip (trade name) PA100 main agent/Bondeip (trade name) PA100 curing agent/isopropanol/water were mixed at a mass ratio of 1/1/2/1.5 to obtain an antistatic layer forming composition 1.

The antistatic layer forming composition 1 was applied in a coating amount of 0.3 g/m² to one surface (the surface being smooth) of the second thermoplastic resin layer and dried to form an antistatic layer. Then, on the surface of the antistatic layer, an adhesive composition 1 obtained by mixing CRISVON NT-258/Coronate 2096/ethyl acetate in a mass ratio of 18/1/80 was applied in a coating amount of 0.5 g/m² and dried to form an adhesive layer. The first thermoplastic resin layer was laminated on the adhesive layer so that the side where there are irregularities became outer side of the mold release film, and dry lamination was conducted under such a condition that the tension exerted to both the first thermoplastic resin layer and the second thermoplastic resin layer would be 8N, thereby to prepare a mold release film with the same construction as the mold release film 1 in the first embodiment.

### [Ex 2]

A mold release film was prepared in the same manner as in Ex. 1 except that the first thermoplastic resin layer and the second thermoplastic resin layer were changed to ETFE film (1-2).

### [Ex. 3]

A mold release film was prepared in the same manner as in Ex. 1 except that the first thermoplastic resin layer and the second thermoplastic resin layer were changed to ETFE film (2-1).

### [Ex. 4]

A mold release film was prepared in the same manner as in Ex. 1 except that the second thermoplastic resin layer was changed to PBT film (1-1), and the tension exerted to the second thermoplastic resin layer at the time of dry lamination was changed from 8N to 13N.

### [Ex. 5]

A mold release film was prepared in the same manner as in Ex. 1 except that the second thermoplastic resin layer was changed to polyamide film (1-1), and the tension exerted to the second thermoplastic resin layer at the time of dry lamination was changed from 8N to 9N.

### [Ex. 6]

A mold release film was prepared in the same manner as in Ex. 4 except that the first thermoplastic resin layer was changed to TPX film (1-1), and the tension exerted to the first thermoplastic resin layer at the time of dry lamination was changed from 8N to 9N.

### [Ex. 7]

A mold release film was prepared in the same manner as in Ex. 1 except that the first thermoplastic resin layer was changed to ETFE film (1-3), and the tension exerted to the first thermoplastic resin layer at the time of dry lamination was changed to 3N.

### [Ex. 8]

By adding a conductive polymer A to the adhesive composition 1, an antistatic layer forming composition 2 was prepared. The addition amount of the conductive polymer A was, as calculated as solid content, 30 mass % to the adhesive component. A mold release film was prepared in the same manner as in Ex. 1 except that instead of the antistatic layer forming composition 1 and the adhesive composition 1, the antistatic layer forming composition 2 was used.

### [Ex. 9]

Pelestat NC6321 was dissolved in ethyl acetate so as to be 10 mass %, to obtain an antistatic layer forming composition 3. A mold release film was prepared in the same manner as in Ex. 1 except that instead of the antistatic layer forming composition 1, the antistatic layer forming composition 3 was used.

### [Ex. 10]

ETFE (3 parts by mass of carbon black kneaded) film (1-1) was used as it was, as a release film.

### [Ex. 11]

A mold release film was prepared in the same manner as in Ex. 1 except that no antistatic layer forming composition 1 was used.

### [Ex. 12]

A mold release film was prepared in the same manner as in Ex. 1 except that the second thermoplastic resin layer was changed to PET film (1-2), and the tension exerted to the second thermoplastic resin layer at the time of dry lamination was changed from 8N to 26N.

### [Ex. 13]

A mold release film was prepared in the same manner as in Ex. 1 except that the second thermoplastic resin layer was changed to PET film (1-1), and the tension exerted to the second thermoplastic resin layer at the time of dry lamination was changed from 8N to 30N.

With respect to the mold release films in Ex. 1 to 13, the value of {(E₁′×T₁×W₁)×F₂}/{(E₂′×T₂×W₂)×F₁} at the time of dry lamination, the peel strength at 180° C., the surface resistance of the antistatic layer, the elastic modulus (storage elastic modulus E′ (25) at 25° C. and storage elastic modulus E′ (180) at 180° C.) of each of the first thermoplastic resin layer and the second thermoplastic resin layer, and the results of the ash adhesion test, the 180° C. followability test, the curl test and the mold contamination, are shown in Tables 1 and 2.

TABLE 1

| | | | Ex. | | | | | |
|---|---|---|---|---|---|---|---|---|
| | | | 1 | 2 | 3 | 4 | 5 | 6 |
| Film | First thermoplastic resin layer | | ETFE film | ETFE film | ETFE film | ETFE film | ETFE film | TPX film |
| construction | | | (1-1) | (1-2) | (2-1) | (1-1) | (1-1) | (1-1) |
| | Interlayer | Composition to form | Adhesive | Adhesive | Adhesive | Adhesive | Adhesive | Adhesive |
| | | adhesive layer | composition 1 | composition 1 | composition 1 | composition 1 | composition 1 | composition 1 |
| | | Material to form | Antistatic | Antistatic | Antistatic | Antistatic | Antistatic | Antistatic |
| | | antistatic layer | layer forming | layer forming | layer forming | layer forming | layer forming | layer forming |
| | | | composition 1 | composition 1 | composition 1 | composition 1 | composition 1 | composition 1 |

| | | | | | | |
|---|---|---|---|---|---|---|
| Second thermoplastic resin layer | ETFE film | ETFE film | ETFE film | PBT film | Polyamide | PBT film |
| | (1-1) | (1-2) | (2-1) | (1-1) | film (1-1) | (1-1) |

| Tension (N) exerted to first thermoplastic resin | | 8/8 | 8/8 | 8/8 | 8/13 | 8/9 | 9/13 |
|---|---|---|---|---|---|---|---|
| layer/second thermoplastic resin layer | | | | | | | |
| {(E₁′ × T₁ × W₁) × F₂}/{(E₂′ × T₂ × W₂) × F₁} | | 1.0 | 1.0 | 1.0 | 0.98 | 1.0 | 1.0 |
| Peel strength (N/cm) at 180° C. | | 1.8 | 1.5 | 1.5 | 1.8 | 1.8 | 1.3 |
| Surface resistance (Ω/□) of antistatic layer | | 1 × 10⁹ | 1 × 10⁹ | 1 × 10⁹ | 1 × 10⁹ | 1 × 10⁹ | 1 × 10⁹ |
| Elastic modulus (MPa) | E′(25) | 900 | 900 | 800 | 900 | 900 | 1,200 |
| of first thermoplastic | E′(180) | 40 | 40 | 10 | 40 | 40 | 30 |
| resin layer | | | | | | | |
| Elastic modulus (MPa) | E′(25) | 900 | 900 | 800 | 1,800 | 1,200 | 1,800 |
| of second thermoplastic | E′(180) | 40 | 40 | 10 | 120 | 280 | 120 |
| resin layer | | | | | | | |

| | | | | | | |
|---|---|---|---|---|---|---|
| Ash adhesion test | ◯ | ◯ | ◯ | ◯ | ◯ | ◯ |
| 180° C. followability test | ◯ | ◯ | ◯ | ◯ | ◯ | ◯ |
| Curl test | ◯ (0 cm) | ◯ (0 cm) | ◯ (0 cm) | ◯ (0.7 cm) | ◯ (0.3 cm) | ◯ (0.5 cm) |
| Mold contamination | ◯ | ◯ | ◯ | ◯ | ◯ | ◯ |

TABLE 2

| | | | Ex. | | | | | | |
|---|---|---|---|---|---|---|---|---|---|
| | | | 7 | 8 | 9 | 10 | 11 | 12 | 13 |
| Film | First thermoplastic | | ETFE film | ETFE film | ETFE film | ETFE (3 | ETFE film | ETFE film | ETFE film |
| construction | resin layer | | (1-3) | (1-1) | (1-1) | pats by | (1-1) | (1-1) | (1-1) |
| | Interlayer | Composition | Adhesive | Adhesive | Adhesive | mass of | Adhesive | Adhesive | Adhesive |
| | | to form | composition 1 | layer | composition 1 | carbon | composition | composition 1 | composition 1 |
| | | adhesive | | forming | | black | 1 | | |
| | | layer | | composition 2 | | kneaded) | | | |
| | | Material to | Antistatic | | Antistatic | film (1-1) | | Antistatic | Antistatic |
| | | form | layer | | layer | | | layer | layer |
| | | antistatic | forming | | forming | | | forming | forming |
| | | layer | composition 1 | | composition 3 | | | composition 1 | composition 1 |

| | | | | | | |
|---|---|---|---|---|---|---|
| Second thermoplastic | ETFE film | ETFE film | ETFE film | ETFE film | PET film | PET film |
| resin layer | (1-1) | (1-1) | (1-1) | (1-1) | (1-2) | (1-1) |

| Tension (N) exerted to first | | 3/8 | 8/8 | 8/8 | — | 8/8 | 8/26 | 8/30 |
|---|---|---|---|---|---|---|---|---|
| thermoplastic resin layer/second | | | | | | | | |
| thermoplastic resin layer | | | | | | | | |
| {(E₁′ × T₁ × W₁) × F₂}/{(E₂′ × T₂ × | | 1.07 | 1.0 | 1.0 | — | 1.0 | 1.0 | 1.0 |
| W₂) × F₁} | | | | | | | | |
| Peel strength (N/cm) at 180° C. | | 1.5 | 0.3 | 1.8 | — | 1.8 | 1.6 | 1.8 |
| Surface resistance (Ω/□) of antistatic | | 1 × 10⁹ | 1 × 10⁸ | 1 × 10¹⁰ | 1 × 10⁹ | 1 × 10¹⁵ | 1 × 10⁹ | 1 × 10⁹ |
| layer | | | | | | | | |
| Elastic modulus (MPa) | E′(25) | 900 | 900 | 900 | 1,500 | 900 | 900 | 900 |
| of first thermoplastic | E′(180) | 40 | 40 | 40 | 120 | 40 | 40 | 40 |
| resin layer | | | | | | | | |
| Elastic modulus (MPa) | E′(25) | 900 | 900 | 900 | — | 900 | 3,000 | 4,000 |
| of second | E′(180) | 40 | 40 | 40 | — | 40 | 90 | 580 |
| thermoplastic resin | | | | | | | | |
| layer | | | | | | | | |

| | | | | | | | |
|---|---|---|---|---|---|---|---|
| Ash adhesion test | ◯ | ◯ | ◯ | ◯ | X | ◯ | ◯ |
| 180° C. followability test | ◯ | Δ | ◯ | ◯ | ◯ | ◯ | X |
| Curl test | ◯ (0.8 cm) | ◯ (0 cm) | ◯ (0 cm) | ◯ (0 cm) | ◯ (0 cm) | X (1.3 cm) | X (1.5 cm) |
| Mold contamination | ◯ | ◯ | ◯ | X | ◯ | ◯ | ◯ |

As shown in the above results, the mold release films in Ex. 1 to 9 showed no adhesion of ash in the ash adhesion test and were ones less likely to be electrically charged. Further, their evaluation results of the 180° C. followability test, the curl test and the mold contamination were also good. Whereas, in the mold release film in Ex. 10 having carbon black blended, mold contamination was observed. On the mold release film in Ex. 11 wherein the interlayer contained no polymeric antistatic agent, the ash deposited in the ash adhesion test. With the mold release film in Ex. 12 wherein the difference in storage modulus at 25° C. between the first thermoplastic resin layer and the second thermoplastic resin layer exceeded 1,200 MPa, the curl was large.

With the mold release film in Ex. 13 wherein the difference in storage modulus at 25° C. between the first thermoplastic resin layer and the second thermoplastic resin layer exceeded 1,200 MPa and the elastic modulus at 180° C. of the second thermoplastic resin layer exceeded 300 MPa, the mold followability was poor, and the carl was large.

### INDUSTRIAL APPLICABILITY

The mold release film of the present invention is widely useful in the production of semiconductor package modules, etc.

This application is a continuation of PCT Application No. PCT/JP2015/056732, filed on Mar. 6, 2015, which is based upon and claims the benefit of priority from Japanese Patent Application No. 2014-045460 filed on Mar. 7, 2014. The contents of those applications are incorporated herein by reference in their entireties.

### REFERENCE SYMBOLS

1: mold release film, 2: first thermoplastic resin layer, 3: second thermoplastic resin layer, 4: interlayer, 10: substrate, 12: semiconductor chip (semiconductor element), 14: resin sealed portion, 14a: upper surface of resin sealed portion 14, 16: ink layer, 18: bonding wire, 19: cured product, 20: fixed upper mold, 22: cavity bottom member, 24: movable lower mold, 26: cavity, 30: mold release film, 40: curable resin, 50: upper mold, 52: lower mold, 54: cavity, 56: cavity surface, 58: substrate placement portion, 60: resin introduction portion, 62: resin placement portion, 64: plunger, 70: substrate, 72: semiconductor chip (semiconductor element), 74: underfill (resin sealed portion), 80: mesh, 82: mesh, 84: exhaust port, 90: frame material, 92: jig, 92A: upper member, 92B: lower member, 94: weight, 96: hot plate, 98: frame, S: space, L1: piping, L2: piping, 110: semiconductor package, 120: semiconductor package

What is claimed is:

1. A mold release film to be disposed on a surface of a mold which is to be in contact with a curable resin, in a process for producing a semiconductor package by disposing a semiconductor element in the mold, and sealing it with the curable resin to form a resin sealed portion, characterized by comprising
a first thermoplastic resin layer to be in contact with the curable resin at the time of forming the resin sealed portion, a second thermoplastic resin layer to be in contact with the mold at the time of forming the resin sealed portion, and an interlayer disposed between the first thermoplastic resin layer and the second thermoplastic resin layer, wherein
the first thermoplastic resin layer and the second thermoplastic resin layer have a storage elastic modulus at 180° C. of from 10 to 300 MPa, respectively, the difference in storage elastic modulus at 25° C. between them is at most 1,200 MPa, and their thicknesses are from 12 to 50 μm, and
the interlayer includes a layer containing a polymeric antistatic agent.

2. The mold release film according to claim 1, wherein the interlayer is one having the layer containing a polymeric antistatic agent, and an adhesive layer formed from an adhesive containing no polymeric antistatic agent or an adhesive layer containing a polymeric antistatic agent.

3. The mold release film according to claim 1, wherein both the first thermoplastic resin layer and the second thermoplastic resin layer do not contain an inorganic additive.

4. The mold release film according to claim 1, wherein the peel strength between the first thermoplastic resin layer and the second thermoplastic resin as measured at 180° C. in accordance with JIS K6854-2, is at least 0.3 N/cm.

5. The mold release film according to claim 1, wherein the surface resistance of the layer containing a polymeric antistatic agent is at most 10¹⁰Ω/□.

6. The mold release film according to claim 1, wherein the curl as measured by the following measuring method is at most 1 cm:
(Method for Measuring the Curl)
At from 20 to 25° C., a square-shaped mold release film of 10 cm×10 cm is left to stand still on a flat metal plate for 30 seconds, whereby the maximum height (cm) of the portion lifted from the metal plate, of the mold release film, is measured, and the measured value is adopted as the curl.

7. A process for producing a semiconductor package having a semiconductor element and a resin sealed portion formed from a curable resin for sealing the semiconductor element, characterized by comprising
a step of disposing a mold release film as defined in claim 1 on a surface of a mold which is to be in contact with a curable resin,
a step of disposing a substrate having a semiconductor element mounted thereon, in the mold, and filling a curable resin in a space in the mold, followed by curing to form a resin sealed portion, thereby to obtain a sealed body having the substrate, the semiconductor element and the resin sealed portion, and
a step of releasing the sealed body from the mold.

8. The process for producing a semiconductor package according to claim 7, wherein in the step of obtaining a sealed body, a part of the semiconductor element is in direct contact with said release film.

9. A process for producing a mold release film, comprising a step of dry laminating a first film for forming a first thermoplastic resin layer and a second film for forming a second thermoplastic resin layer, by using an adhesive, characterized in that
the storage elastic modulus E₁′ (MPa), the thickness T₁ (μm), the width W₁ (mm) and the tensile force F₁ (N) exerted thereon, at the dry lamination temperature t (° C.), of one of the first film and the second film, and the storage modulus E₂′ (MPa), the thickness T₂ (μm), the width W₂ (mm) and the tensile force F₂ (N) exerted thereon at the dry lamination temperature t (° C.), of the other film, satisfy the following formula (I),
0.8≦{(E₁′×T₁×W₁)×F₂}/{(E₂′×T₂×W₂)×F₁}≦1.2 (I)
wherein the storage elastic modulus E₁′ (180) and E₂′ (180) at 180° C. are from 10 to 300 MPa, the difference in storage elastic modulus at 25° C. i.e. |E₁′ (25)−E₂′ (25)| is at most 1,200 MPa, and T₁ and T₂ are, respectively, from 12 to 50 (μm).
